(19) United States
(12) Patent Application Publication
(10) Pub. No.: US 2025/0215565 A1
(43) Pub. Date: Jul. 3, 2025

(54) VANADIUM CONTAINING LAYERS AND METHODS AND SYSTEMS FOR DEPOSITING SAID LAYERS

(71) Applicant: ASM IP Holding B.V., Almere (NL)

(72) Inventors: Jocelyn Kofi Brobbey, Phoenix, AZ (US); Petro Deminskyi, Espoo (FI); Michael Eugene Givens, Oud-Heverlee (BE); Giuseppe Alessio Verni, Ismaning (DE); Patricio Eduardo Romero, Wilsele (BE); Mikko Leander Nisula, Espoo (FI)

(21) Appl. No.: 19/007,864

(22) Filed: Jan. 2, 2025

Related U.S. Application Data
(60) Provisional application No. 63/617,238, filed on Jan. 3, 2024.

(51) Int. Cl. C23C 16/455; C23C 16/14; C23C 16/18; C23C 16/34; C23C 16/44; C23C 16/52; C23C 16/56

(52) U.S. Cl. CPC C23C 16/45553; C23C 16/14; C23C 16/18; C23C 16/34; C23C 16/4408; C23C 16/45544; C23C 16/52; C23C 16/56

(57) ABSTRACT

The present disclosure generally relates to structures comprising one or more vanadium containing layers and to methods and systems for forming said structures. In some embodiments, the structures comprise a first vanadium containing layer that is formed using a cyclic deposition process. The cyclic deposition process comprises providing a substrate in a reaction space, contacting a surface of the substrate with a vanadium precursor, and contacting the surface of the substrate with a reducing agent to form the first vanadium containing layer on the surface of the substrate. In some embodiments, a second vanadium containing layer is formed on or over the first vanadium containing layer and/or from the first vanadium containing layer.

### CROSS-REFERENCE TO RELATED APPLICATION(S)

This Application claims the benefit of U.S. Provisional Application 63/617,238 filed on Jan. 3, 2024, the entire contents of which is incorporated herein by reference.

### FIELD

The present disclosure generally relates to the field of semiconductor processing methods and systems. In particular, the present disclosure generally relates to structures that comprise one or more vanadium containing layers and to methods and systems for forming said structures.

### BACKGROUND

Vanadium containing thin films have several potential applications in next generation semiconductor devices. Vanadium may be useful in front end-of-the-line applications as a gate metal, a source/drain contact material, a silicide contact layer, and/or as a component in work function or threshold voltage tuning layers. Vanadium may also be useful in back end-of-the-line applications as a contact material and/or as an interconnect material, for example, as a seed layer, an adhesion layer, a barrier layer, or as a metal fill. However, the formation of films from electropositive metals, such as vanadium, is challenging with few known solutions all of which have significant limitations. For example, reduction of the metal using vapor deposition methods often requires plasma-based approaches or unusual process conditions in the case of thermal approaches. Thus, improved methods for deposition of vanadium containing films are of high interest. The present disclosure addresses and meets these needs.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

The present disclosure generally relates to structures that comprise one or more vanadium containing layers and to methods and systems for forming said structures. Such vanadium containing layers may be useful in the formation of semiconductor device structures.

An aspect of the present disclosure relates to structures that comprise one or more vanadium containing layers. In embodiments, the structure comprises a substrate and one or more vanadium containing layers positioned on a surface of the substrate. In some embodiments, at least one of the one or more vanadium containing layers comprises vanadium nitride or a vanadium chalcogenide.

In some embodiments, the structure comprises a first vanadium containing layer and a second vanadium containing layer. In some of these embodiments, the second vanadium containing layer comprises vanadium nitride or a vanadium chalcogenide. The vanadium chalcogenide may be one or more of vanadium sulfide, vanadium selenide, and vanadium telluride. In some embodiments, the vanadium chalcogenide is vanadium dichalcogenide.

In some embodiments, at least one of the vanadium containing layers comprises metallic vanadium. In some embodiments, at least one of the vanadium containing layer comprises vanadium in an oxidation state of 0.

In some embodiments, at least one of the vanadium containing layers comprises vanadium in an oxidation state of +2 or +3.

In some embodiments, at least one of the vanadium containing layers comprises vanadium nitride. In some embodiments, the second vanadium layer comprises vanadium nitride.

In some embodiments, at least one of the vanadium containing layers comprises a vanadium chalcogenide. In some embodiments, the second vanadium layer comprises a vanadium chalcogenide. The vanadium chalcogenide may be one or more of vanadium sulfide, vanadium selenide, and vanadium telluride. In some embodiments, the vanadium chalcogenide is vanadium dichalcogenide.

In some embodiments, at least one of the vanadium containing layers comprises an electrical resistivity of less than 100 μΩ-cm at an average thickness of less than about 20 nm, or at an average thickness of less than about 10 nm, or at an average thickness of less than about 5 nm, or at an average thickness of less than about 2 nm, or even at an average thickness of less than about 1 nm.

In some embodiments, the structure further comprises one or more dielectric layers positioned on the surface of the substrate below the one or more vanadium containing layers. At least one of the one or more dielectric layers may comprise a high-κ material.

Another aspect of the present disclosure relates to methods for forming structures comprising one or more vanadium containing layers described in any of the above paragraphs. In embodiments, the method comprises providing a substrate in a reaction space and forming a vanadium containing layer on the surface of the substrate. In some embodiments, the vanadium containing layer is a first vanadium containing layer and the method further comprises, after the forming of the first vanadium containing layer, forming a second vanadium containing layer on the surface of the substrate. The second vanadium containing layer may be formed on or over the first vanadium containing layer and/or from the first vanadium containing layer.

In some embodiments, the method further comprises heating the substrate to a temperature of at least about 40° C. to no more than about 600° C. In some embodiments, the substrate is heated to a temperature from about 100° C. to about 600° C., or from about 150° C. to about 500° C.

In some embodiments, the method further comprises annealing the substrate. The annealing may be performed after the formation of the first vanadium containing layer and/or after the formation of the second vanadium containing layer. The annealing may occur at a temperature at least about 300° C. to no more than about 1,200° C. for a set period of time, typically the annealing temperature is at least about 400° C. and no more than about 600° C.

In some embodiments, the step of forming the first vanadium containing layer comprises performing at least one deposition cycle of a first cyclic deposition process comprising contacting the surface of the substrate with a vanadium precursor; and contacting the surface of the substrate with a reducing agent, thereby forming the first vanadium containing layer on the surface of the substrate. In some embodiments the method further comprises purging the reaction space between the contacting steps.

In some embodiments, the vanadium precursor comprises a vanadium halide. The vanadium halide may be selected from the group consisting of vanadium fluoride, vanadium chloride, vanadium bromide, vanadium iodide, vanadium oxyfluoride, vanadium oxychloride, vanadium oxybromide, vanadium oxyiodide, and combinations thereof. In some embodiments, the vanadium precursor is vanadium tetrachloride (VCl₄) or vanadium oxytrichloride (VOCl₃).

In some embodiments, the reducing agent comprises indium. In some embodiments, the reducing agent is an organoindium compound. In some embodiments, the reducing agent comprises an alkylindium compound. The alkylindium compound may be selected from the group consisting of trimethylindium, tricthylindium, tri-isopropylindium, tri-tertbutylindium, and combinations thereof. In some embodiments, the reducing agent is trimethylindium.

In some embodiments, the first cyclic deposition process is a thermal deposition process.

In some embodiments, the step of forming the second vanadium containing layer comprises contacting the surface of the substrate with a co-reactant. The co-reactant may be one or more of a nitrogen reactant and a chalcogen reactant. The chalcogen reactant may comprise one or more of sulfur, selenium, and tellurium.

In some embodiments, the step of forming the second vanadium containing layer comprises performing at least one deposition cycle of a second cyclic deposition process comprising contacting the surface of the substrate with a vanadium precursor; and contacting the surface of the substrate with a co-reactant. The co-reactant may be one or more of a nitrogen reactant and a chalcogen reactant.

In some embodiments, the co-reactant is a nitrogen reactant and the second vanadium containing layer comprises vanadium nitride.

In some embodiments, the co-reactant is a chalcogen reactant and the second vanadium containing layer comprises a vanadium chalcogenide. The chalcogen reactant may comprise one or more of sulfur, selenium, and tellurium. The vanadium chalcogenide may be one or more of vanadium sulfide, vanadium selenide, and vanadium telluride. In some embodiments, the vanadium chalcogenide may be vanadium dichalcogenide.

Other aspects of the present disclosure relate to systems for forming structures comprising the one or more vanadium containing layers described in any of the above related paragraphs, using the methods described in any of the above related paragraphs.

These and other embodiments will become readily apparent to those skilled in the art from the following detailed description of certain embodiments having reference to the attached figures. The invention is not being limited to any particular embodiments disclosed.

### BRIEF DESCRIPTION OF DRAWINGS

The accompanying drawings constitute part of the specification. The drawings are included to provide a further understanding of the disclosure, and together with the description explain certain principles of the disclosure. The drawings illustrate exemplary embodiments of how the disclosure can be made and used and are not to be construed as limiting the disclosure to only the illustrated and described examples. It will be appreciated that elements in the figures are illustrated for simplicity and clarity and have not necessarily been drawn to scale. The illustrations presented herein are not meant to be actual views of any particular material, structure, or device, but are merely idealized representations that are used to describe embodiments of the disclosure. For example, the dimensions of some of the elements in the figures may be exaggerated relative to other elements to help improve understanding of illustrated embodiments of the present disclosure. Further features and advantages will become apparent from the following, more detailed, description of various aspects, embodiments, and configurations of the disclosure, as illustrated by the drawings referenced below.

FIG. 1A and FIG. 1B show pictorial representations of exemplary embodiments of structures comprising one or more vanadium containing layers. The thicknesses of various material layers, relative to one another, are not drawn to scale.

FIG. 2 is a process flow diagram of a method for forming a structure comprising a vanadium containing layer on a surface of a substrate according to an embodiment of the present disclosure. Optional steps are shown by the features or elements in the dashed lines.

FIG. 3 is a process flow diagram of a method for forming a structure comprising a first vanadium containing layer and a second vanadium containing layer on a surface of a substrate according to an embodiment of the present disclosure. Optional steps are shown by the features or elements in the dashed lines.

FIG. 4 is a process diagram of a cyclic deposition method for forming a vanadium containing layer according to some embodiment of the disclosure. Optional process steps are shown by the features or elements in the dashed lines.

FIG. 5 is a process diagram of a cyclic deposition method for forming a (first) vanadium containing layer according to some embodiment of the disclosure. Optional process steps are shown by the features or elements in the dashed lines.

FIG. 6 is a process diagram of a cyclic deposition method for forming a vanadium nitride containing layer according to some embodiment of the disclosure. Optional process steps are shown by the features or elements in the dashed lines.

FIG. 7 is a process diagram of a cyclic deposition method for forming a vanadium chalcogenide containing layer according to some embodiment of the disclosure. Optional process steps are shown by the features or elements in the dashed lines.

FIG. 8 is a schematic presentation of a vapor deposition assembly according to an embodiment of the present disclosure.

FIG. 9A and FIG. 9B shows pictorial representations of exemplary embodiments of an intermediate structure for forming a gate stack. The intermediate structures comprise one or more vanadium containing layers. The thicknesses of various material layers, relative to one another, are not drawn to scale.

### DETAILED DESCRIPTION

The description of embodiments of compositions, methods, systems, and structures provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. Unless otherwise noted, the exemplary embodiments or components thereof may be combined or may be applied separate from each other. The headings provided herein, if any, are for convenience only and do not necessarily affect the scope or meaning of the claimed invention.

As used herein, “atomic layer deposition”, abbreviated as “ALD”, refers to a vapor deposition process in which deposition cycles, such as a plurality of consecutive deposition cycles, are conducted in a reaction space (i.e., one or more reaction chambers). Generally, in ALD processes, during each deposition cycle, a precursor is introduced into a reaction space and is chemisorbed onto a substrate surface, which may include a previously deposited material from a previous ALD cycle or other materials, forming maximally one monolayer of the precursor that does not readily react with additional excess precursor (i.e., a self-limiting reaction). Thereafter, in some cases, another precursor or a reactant may be introduced into the reaction space to convert the chemisorbed precursor to the desired material on the substrate surface. Other reaction steps may be included in the deposition cycle. ALD, as used herein, may also be meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of reactants.

As used herein, “chemical vapor deposition”, abbreviated as “CVD”, refers to a vapor deposition process in which a film is deposited on a substrate by exposing its surface to one or more gaseous precursors and reactants, which react and/or decompose on the substrate surface to form the film. The precursors and/or reactants can be provided simultaneously to the reaction space, or in partially or completely separated pulses. The substrate and/or reaction space can be heated to promote the reaction between the gaseous precursors and/or reactants. In some embodiments, the precursors and/or reactants are provided until a layer having a desired thickness is deposited. In some embodiments, a cyclic CVD process can be used with multiple cycles to deposit a thin film having a desired thickness. In cyclic CVD processes, the precursors and/or reactants may be provided to the reaction space in pulses that do not overlap, or that partially or completely overlap.

As used herein, a “cyclic deposition process” refers to a method or a process comprising sequentially introducing precursors and/or reactants into a reaction space to deposit a layer or a film on or over a substrate and includes processing techniques such as ALD, cyclical CVD, and hybrid cyclical deposition processes that include an ALD component and a cyclical CVD component. In preferred embodiments, a cyclic deposition process as disclosed herein refers to an ALD process.

As used herein, a “film” or “layer”, which may be used interchangeably, refers to a continuous, substantially continuous, or non-continuous material that extends in a direction perpendicular to a thickness direction to cover at least a portion of a surface. A film may be positioned on a lateral surface and/or on a sidewall of recessed features of a surface. A film can include two-dimensional materials, three-dimensional materials, nanoparticles, partial or full molecular layers, partial or full atomic layers, and/or clusters of atoms or molecules. A film may be built up from one or more non-discernable monolayers or sub-monolayers to produce a uniform or a substantially uniform material, wherein the number of monolayers or sub- monolayers influences the thickness of the film.

As used herein, a “gas” refers to a state of mater consisting of atoms or molecules that have neither a defined volume nor shape. A gas includes vaporized solid and/or liquid and may be referred to as a vapor. A gas may be constituted by a single gas or a mixture of gases, depending on the context.

As used herein, a “precursor” refers to a compound that participates in a chemical reaction to form another compound or element, wherein a portion of the precursor (an element or group within the precursor) is incorporated into the compound or element that results from the chemical reaction. The compound or element that results from the chemical reaction may be a layer and/or a film that is formed on a surface of a substrate.

As used herein, the term “purge” may refer to a procedure in which vapor phase precursors, reactants, and/or vapor phase byproducts are removed from a substrate surface for example by evacuating the reaction space with a vacuum pump and/or by replacing the gas inside a reaction space with an inert or substantially inert gas such as argon or nitrogen. Purging may be affected between two pulses of gases which react with each other. Purging may also be affected between two pulses of gases that do not react with each other. For example, a purge or purging may be provided between pulses of two precursors or between a precursor and a reactant. Purging may avoid or at least reduce gas-phase interactions between the two gases reacting with each other. It shall be understood that a purge can be affected either in time or in space, or both. For example, in the case of temporal purges, a purge step can be used, for example, in a temporal sequence of providing a first reactant to a reaction space, providing a purge gas to the reaction space, and providing a second reactant to the reaction space, wherein the substrate on which a layer is deposited does not move. For example, in the case of spatial purges, a purge step can comprise moving a substrate from a first location to which a first reactant is continually supplied, through a purge gas curtain, to a second location to which a second reactant is continually supplied.

As used herein, a “reactant” refers to a compound that participates in a chemical reaction to form another compound or element. In some instances, a reactant is a precursor. In other instances, the compound or element that results from the chemical reaction does not contain a portion, or a significant portion, of the reactant (an element or group within the reactant) and therefore the reactant is not a precursor. By way of non-limiting example, a reducing agent is a reactant.

As used herein, a “substrate” refers to an underlying material or materials that may be used to form, or upon which, a device, a circuit, a material, or a material layer may be formed. The substrate may be continuous or non-continuous; rigid or flexible; solid or porous; and combinations thereof. The substrate may be in any form, such as, for example, a powder, a sheet, a plate, or a workpiece. Substrates in the form a sheet may extend beyond the bounds of a process/reaction chamber where a deposition process occurs and, in some cases, move through the chamber such that the process continues until the end of the substrate is reached. Substrates in the form of a plate may include wafers in various shapes and sizes. Substrates may be made from semiconductor materials, including, for example, silicon, silicon germanium, silicon oxide, gallium arsenide, gallium nitride, and silicon carbide. A substrate can include one or more layers overlying a bulk material, for example the substrate may include nitrides, for example TiN, oxides, insulating materials, dielectric materials, conductive materials, metals, such as tungsten, ruthenium, molybdenum, cobalt, aluminum, or copper, or other metallic materials, crystalline materials, epitaxial, heteroepitaxial, and/or single crystal materials. The substrate can include various topologies, such as, for example, gaps, recesses, lines, trenches, vias, holes, or spaces between elevated portions, such as fins, and the like formed within or on at least a portion of a layer of the substrate.

As used herein, a “structure” can be or includes a substrate as described herein. Structures can include one or more layers overlying the substrate, such as one or more layers formed according to a method as described herein. Device portions can be or include structures. Likewise, intermediate device portions can be or include structures.

Articles “a” or “an” refer to a species or a genus including multiple species, depending on the context. As such, the terms “a/an”, “one or more”, and “at least one” can be used interchangeably herein.

The terms “comprising”, “including”, and “having” are open ended and do not exclude the presence of other elements or components, unless the context clearly indicates otherwise. Comprising, including, and having can be used interchangeably and include the meaning of “consisting of”. The phrase “consisting of”, however, indicates that no other features or components are present other than those mentioned, unless the context clearly indicates otherwise.

The term “about” as applied to a value generally refers to a range of numbers that is considered to be equivalent to the recited value (e.g., having the same function or result). In some instances, the term “about” may include numbers that are rounded to the nearest significant figure.

The term “essentially” as applied to a composition, a method, a system, or a structure generally means that the additional components do not substantially modify the properties, characteristics, and/or function of the composition, the method, the system, or the structure.

The term “substantially” as applied to a composition, a method, a system, or a structure generally refers to a proportion of a value, a property, a characteristic, or the like, or conversely a lack thereof, that is at least about 70%, or at least about 80%, or at least about 90%, or at least about 95%, or at least about 97%, or at least about 98%, or at least about 99%, or at least about 99.5%, or at least about 99.9%, or more, or any proportion between about 70% and about 100%. In some embodiments, the term “substantially” means a proportion of about 90%, or about 95%, or about 97%, or about 98%, or about 99%, or about 99.5%, or about 99.9%.

The terms “on” or “over” may be used to describe a relative location relationship. For example, an element, a film, or a layer may be directly positioned on or over and physically contacting at least a portion another element, film, or layer; or, alternatively, an element, a film, or a layer may be on or over another element, film or layer but have one or more interposed elements, films, or layers therebetween. Therefore, unless the term “directly” is separately used, the terms “on” or “over” will be construed to be a relative concept. Similar to this, it will be understood that the terms “under”, “underlying”, or “below” describe a relative location relationship and should be construed to be relative concepts.

The terms “at least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C”, and “A, B, and/or C” means A alone, B alone, C alone, A and B together, A and C together, B and C together, or A, B, and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Z₁).

It should be understood that every numerical range given throughout this disclosure is deemed to include the upper and the lower end points, and each and every narrower numerical range that falls within such broader numerical range, as if such narrower numerical ranges were all expressly written herein. By way of example, the phrase “from about 2 to about 4” or “from 2 to 4” includes 2 and 4 and the whole number and/or integer ranges from about 2 to about 3, from about 3 to about 4, and each possible range based on real (e.g., irrational and/or rational) numbers, such as from about 2.1 to about 3.9, from about 2.1 to about 3.4, and so on.

In this disclosure, any defined meanings do not necessarily exclude ordinary and customary meanings, in some embodiments.

Vanadium containing thin films have a variety of applications in next generation semiconductor devices. However, the reduction of electropositive metals, such as vanadium, using vapor deposition methods is challenging with few known solutions. In this regard, the present disclosure is related to structures comprising one or more vanadium containing layers and to methods for forming said structures and vanadium containing layers using a cyclic deposition process and to systems for performing said methods. In particular, in some embodiments, a vanadium halide precursor and an organoindium reducing agent are used to provide vanadium containing layers that may be useful as one or more of an interlayer, an intermediate layer, or a seed layer in the formation of semiconductor device structures. For example, such layers may be used to form a vanadium nitride layer or a vanadium chalcogenide layer with a beneficially low resistivity. These and other advantages will be apparent from the disclosure of the various aspects, embodiments and configurations contained herein.

Aspects of the present disclosure relate to structures that comprise one or more vanadium containing layers and to methods for forming said structures. In some embodiments the structure comprises a vanadium containing layer. In some embodiments, the structure comprises a first vanadium containing layer and a second vanadium containing layer. In certain embodiments, the structure comprises a vanadium nitride layer. In certain other embodiments, the structure comprises a vanadium chalcogenide layer.

As used herein, a “vanadium containing layer” or a “vanadium containing film”, which may be used interchangeably, is a material layer that comprises vanadium. The composition of the vanadium containing layer may depend upon the specific process conditions used to form the layer. The oxidation state of vanadium in the vanadium containing layer may be 0, +2, +3, +4, or +5. In some embodiments, the oxidation state of vanadium in the vanadium containing layer is +2 or +3. In some embodiment, the vanadium containing layer comprises metallic vanadium; hence the oxidation state of vanadium in the vanadium containing layer is 0. In some embodiments, a vanadium content of the vanadium containing layer is at least about 1.0 atomic percent (at. %) to at most about 99.9 at. %, or from at least about 5.0 at. % to at most about 95.0 at. %, or from at least about 10.0 at. % to at most about 90.0 at. %, or from at least about 20.0 at. % to at most about 80.0 at. %, or from at least about 30.0 at. % to at most about 70.0 at. %, or from at least about 40.0 at. % to at most about 60.0 at. %. In some embodiments, a vanadium content of the vanadium containing layer is at least about 30 at. %, or at least about 40 at. %, or at least about 50 at. %, or at least about 60 at. %., or at least about 70 at. %., or at least about 80 at. %, or least about 90 at. %, or least about 95 at. %, or least about 99 at. %.

In some embodiments, the vanadium containing layer comprises vanadium that is in a low oxidation state. For example, the oxidation state of vanadium in the vanadium containing layer may be 0. In some embodiments, the vanadium containing layer comprises vanadium metal. In some embodiments, the vanadium containing layer consists of, or consist essentially of, vanadium metal. Additionally, or alternatively, the oxidation state of vanadium in the vanadium containing layer may be +2 or +3. In some embodiments, the vanadium containing layer further comprises halides, for example one or more of fluoride, chloride, bromide, and iodide. In some embodiments, the vanadium containing layer comprises a vanadium halide. For instance, in some embodiments, the vanadium containing layer comprises one or more of VF_{X}, VCl_{X}, VBr_{X}, and VI_{X}, where x ranges from about 0.01 to about 3, typically from about 0.1 to about 2, or from about 0.5 to about 1.5. In some embodiments, the halide is chloride. In some embodiments, a halide content of the vanadium containing layer ranges from at least about 0.1 at. % to at most about 75 at. %, or at least about 1 at. % to at most about 70 at. %. In some embodiments, a halide content of the vanadium containing layer ranges from at least about 0.1 at. % to at most about 5 at. %. In some embodiments, a halide content of the vanadium containing layer is no more than about 75 at. %, or no more than about 70 at. %, or no more than about 60 at. %, or no more than about 50 at. %, or no more than about 45 at. %, or no more than about 40 at. %, or no more than about 35 at. %, or no more than about 30 at. %, or no more than about 25 at. %, or no more than about 20 at. %, or no more than about 15 at. %, or no more than about 10 at. %, or no more than about 5 at. %, or no more than about 4 at. %, or no more than about 3 at. %, or no more than about 2 at. %, or no more than about 1 at. %, or no more than about 0.5 at. %. In other embodiments, the vanadium containing layer is free of, or substantially free of, halides.

In some embodiments, the vanadium containing layer comprises nitrogen. In certain embodiments the vanadium containing layer comprises vanadium nitride. In some embodiments, the vanadium containing layer consists of, or consist essentially of, vanadium nitride. In some embodiments, a nitrogen content of the vanadium containing layer ranges from at least about 0.1 at. % to at most about 70 at. %, or at least about 1 at. % to at most about 60 at. %. In some embodiments, a nitrogen content of the vanadium containing layer is no more than about 60 at. %, or no more than about 55 at. %, or no more than about 50 at. %, or no more than about 45 at. %, or no more than about 40 at. %, or no more than about 35 at. %, or no more than about 30 at. %, or no more than about 25 at. %, or no more than about 20 at. %, no more than about 15 at. %, or no more than about 10 at. %, or no more than about 5 at. %, or no more than about 4 at. %, or no more than about 3 at. %, or no more than about 2 at. %, or no more than about 1 at. %, or no more than about 0.5 at. %. In other embodiments, the vanadium containing layer is free of, or substantially free of, nitrogen.

In some embodiments, the vanadium containing layer comprises a chalcogen, such as one or more of sulfur, selenide, and tellurium. In certain embodiments the vanadium containing layer comprises a vanadium chalcogenide, such as one or more of vanadium sulfide, vanadium selenide, and vanadium telluride. In certain embodiments, the vanadium chalcogenide is a vanadium dichalcogenide, such as one or more of vanadium disulfide (VS₂), vanadium diselenide (VSe₂), and vanadium ditelluride (VTe₂). Use of the term “vanadium chalcogenide” includes a vanadium dichalcogenide material. The vanadium dichalcogenide material may be 2D material (e.g., having a two-dimensional crystal structure). In some embodiments, the vanadium containing layer consists of, or consist essentially of, a vanadium chalcogenide. In some embodiments, the vanadium containing layer comprises one or more of VS_{X}, VSe_{X}, and VTe_{X}, where x ranges from about 0.5 to about 3, typically from about 0.75 to about 2.8, or from about 0.9 to about 2.5, or from about 1.5 to 2.3, or about 2. In some embodiments, the amount of chalcogen in the vanadium containing layer may be from about 1at % to about 60 at %, or from about 30 at % to about 60 at %, or from about 35 at % to about 55 at %, or from about 40 at % to about 50 at. %. In some embodiments, a chalcogen content of the vanadium containing layer is no more than about 60 at. %, or no more than about 55 at. %, or no more than about 50 at. %, or no more than about 45 at. %, or no more than about 40 at. %, or no more than about 35 at. %, or no more than about 30 at. %, or no more than about 25 at. %, or no more than about 20 at. %, no more than about 15 at. %, or no more than about 10 at. %, or no more than about 5 at. %, or no more than about 4 at. %, or no more than about 3 at. %, or no more than about 2 at. %, or no more than about 1 at. %, or no more than about 0.5 at. %.

In any of these embodiments, the vanadium containing layer may comprise one or more additional elements. For example, the vanadium containing layer may comprises one or more of oxygen, carbon, hydrogen, nitrogen, and other metals such as indium. In some embodiments, the one or more additional elements may be present in the film as impurities, which may originate, in whole or in part, from the precursor(s), reactant(s), and/or process gasses that are used to deposit the vanadium containing layer. Additionally, or alternatively, in the case of oxygen, the vanadium containing layer may be oxidized upon exposure to oxygen gas in the deposition chamber or upon removal of the film from the deposition chamber. Further, in some embodiments, where the structure comprises two vanadium containing layers or other material layers, one or more additional elements may be present in the film due to migration or diffusion of elements from a neighboring layer. In such cases, the composition of the layer may vary across a thickness direction of the layer.

In some embodiments, the vanadium containing layer further comprises carbon. In some embodiments, the vanadium containing layer comprises vanadium carbide. In some embodiments, a carbon content of the vanadium containing layer ranges from at least about 0.1 at. % to at most about 30 at. %, or at least about 1 at. % to at most about 20 at. %. In some embodiments, a carbon content of the vanadium containing layer is no more than about 30 at. %, or no more than about 25 at. %, or no more than about 20 at. %, or no more than about 15 at. %, or no more than about 10 at. %, or no more than about 5 at. %, or no more than about 4 at. %, or no more than about 3 at. %, or no more than about 2 at. %, or no more than about 1 at. %, or no more than about 0.5 at. %. In some embodiments, the vanadium containing layer is free of, or substantially free of, carbon.

In some embodiments, the vanadium containing layer further comprises oxygen. In some embodiments, the vanadium containing layer comprises vanadium oxide. In some embodiments, an oxygen content of the vanadium containing layer ranges from at least about 0.1 at. % to at most about 75 at. %, or at least about 1 at. % to at most 60 at. %, or at least about 10 at. % to at most 50 at. %. In some embodiments, an oxygen content of the vanadium containing layer is no more than about 60 at. %, or no more than about 55 at. %, or no more than about 50 at. %, or no more than about 45 at. %, or no more than about 40 at. %, or no more than about 35 at. %, or no more than about 30 at. %, or no more than about 25 at. %, or no more than about 20 at. %, or no more than about 15 at. %, or no more than about 10 at. %, or no more than about 5 at. %, or no more than about 4 at. %, or no more than about 3 at. %, or no more than about 2 at. %, or no more than about 1 at. %, or no more than about 0.5 at. %. In other embodiments, the vanadium containing layer is free of, or substantially free of, oxygen.

In some embodiments, the vanadium containing layer further comprises other metals, other than vanadium. For instance, by way of non-limiting example, the vanadium containing layer may further comprise indium. In some embodiments, a content of other metals, other than vanadium, in the vanadium containing layer is no more than about 15 at. %, or no more than about 10 at. %, or no more than about 5 at. %, or no more than about 2 at. %, or no more than about 1 at. %, or no more than 0.5 at. %, or no more than 0.1 at. %, or no more than 0.01 at. %. In some embodiments, a content of other metals, other than vanadium, in the vanadium containing layer is at least about 0.1 at. % to no more than about 2 at. %. In some embodiments, a content of indium in the vanadium containing layer is at least about 0.1 at. % to no more than about 2 at. %. In some embodiments, the vanadium containing layer is free of, or substantially free of, other metals, other than vanadium.

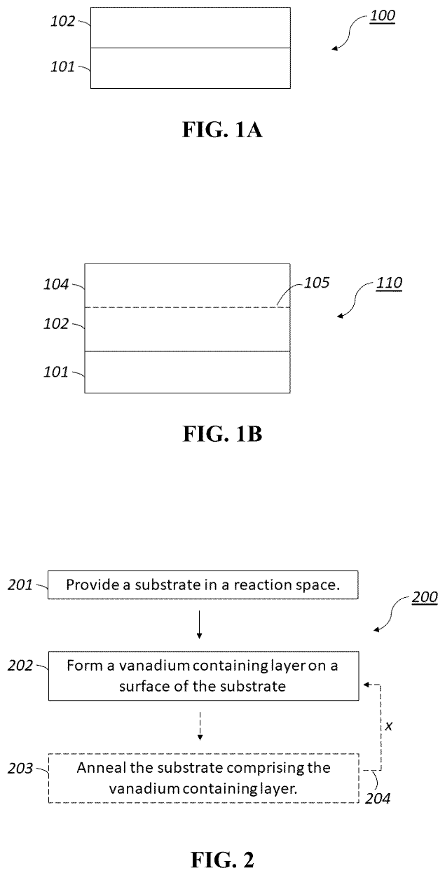

FIG. 1A shows a pictorial representation of an embodiment of a structure 100 comprising a vanadium containing layer 102 positioned on a surface of a substrate 101. According to some embodiments, the vanadium containing layer is a first vanadium containing layer. As shown, the vanadium containing layer 102 is deposited directly on the surface of the substrate 101. However, in practice, the substrate 101 may comprise one or more additional layers and the vanadium containing layer may be positioned on or over the one or more additional layers on the surface of the substrate.

The substrate 101 may be any underlying material or materials that can be used to form, or upon which, the vanadium containing layer 102 can be formed or is formed on. The substrate is not particularly limited and may be a semiconductor wafer or multiple semiconductor wafers. The substrate may comprise one or more material layers such as dielectric layers, insulating layers, metal layers, sacrificial layers, and so forth, in addition to the vanadium containing layer. The substrate may include various topological features, such as gaps, recesses, lines, trenches, vias, holes, or spaces between elevated portions formed within or on at least a portion of a layer of the substrate. In some embodiments, the substrate is a silicon wafer. The silicon wafer may be a monocrystalline silicon wafer (e.g., a p-type monocrystalline silicon wafer). Alternatively, the silicon wafer may comprise silicon-germanium (SiGe). In some embodiments, the substrate comprises a dielectric layer. The dielectric layer may essentially be one material layer, or it can comprise multiple thinner material layers of two or more materials. The dielectric layer may comprise silicon oxide. Additionally, or alternatively, the dielectric layer may comprise high-k material(s). In some embodiments, the substrate further comprises one or more metal layers. The different material layers may form a structure on the surface of the substrate. The structure can be or form part of a CMOS structure, such as one or more of a PMOS and NMOS structure, or other device structures.

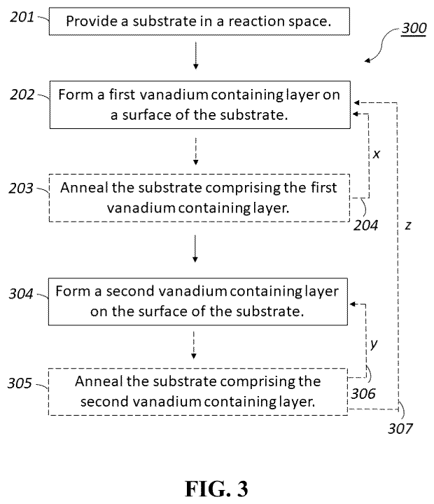

FIG. 2 is a process flow diagram of a method 200 for forming a structure comprising a vanadium containing layer on a surface of a substrate (e.g., sec 100 in FIG. 1A) in accordance with exemplary embodiments of the disclosure. The method 200 comprises providing a substrate in a reaction space 201 and forming a vanadium containing layer on a surface of the substrate 202. In some embodiments, the substrate comprising the vanadium containing layer is optionally annealed 203. The various process steps may optionally be repeated 204 one or more x times. According to some embodiments, the vanadium containing layer produced according to the method 200 of FIG. 2 is a first vanadium containing layer.

As will be elaborated on below, a cyclic deposition process is used to form the (first) vanadium containing layer on the surface of the substrate (e.g., 202 in FIG. 2). In some embodiments, the cyclic deposition process is a first cyclic deposition process. Generally, the cyclic deposition process comprises sequentially contacting a surface of a substrate with a vanadium precursor and a reducing agent co-reactant to form the (first) vanadium containing layer on the surface of the substrate. In preferred embodiment, the vanadium precursor is a vanadium halide, such as vanadium chloride (VCl₄) or vanadium oxychloride (VOCl₃), and the reducing agent is an organoindium compound, such as trimethyl indium (In(CH₃)₃). While not wishing to be bound by a particular theory, the organoindium reducing agent is effective at reducing the vanadium to a low oxidation state. For example, the oxidation state of at least some of the vanadium in the vanadium containing layer may be 0. Additionally, or alternatively, the oxidation state of at least some of the vanadium in the vanadium containing layer may be +2 or +3.

The first vanadium containing layer disclosed herein may be useful as one or more of an interlayer, an intermediate layer, and/or a seed layer. In some embodiments, the first vanadium containing layer may be an interlayer and an outer layer of a second vanadium containing material may be formed on or over the first vanadium containing layer. In other embodiments, the first vanadium containing layer is used an intermediate layer that is converted, at least in part, to a second vanadium containing layer. Regardless of the specific process or combination of processes, the first vanadium containing layer may be useful in forming a second vanadium containing layer with beneficial properties. In some embodiments, the second vanadium containing layer is a capping layer. Without wishing to be bound to a particular theory, it is hypothesized that the presence of metallic vanadium or vanadium in a low oxidation state in the first vanadium layer influences the properties of the second vanadium containing layer. For example, the first vanadium containing layer may be useful in forming a vanadium nitride layer or a vanadium chalcogenide layer that has a low resistivity.

FIG. 1B shows a pictorial representation of another embodiment of a structure 110 comprising a substrate 101 that comprises a second vanadium containing layer 104 positioned directly on or over a first vanadium containing layer 102. The first vanadium containing layer is interposed between a substrate 101 and the second vanadium containing layer 104. The interface 105 between the first vanadium containing layer 102 and the second vanadium containing 104 is shown by a dashed line to indicate that the interface may be distinct or, alternatively, the interface 105 may be less well defined or not defined at all. One or more additional layers (not shown) may be present on the surface of the substrate under the first vanadium containing layer.

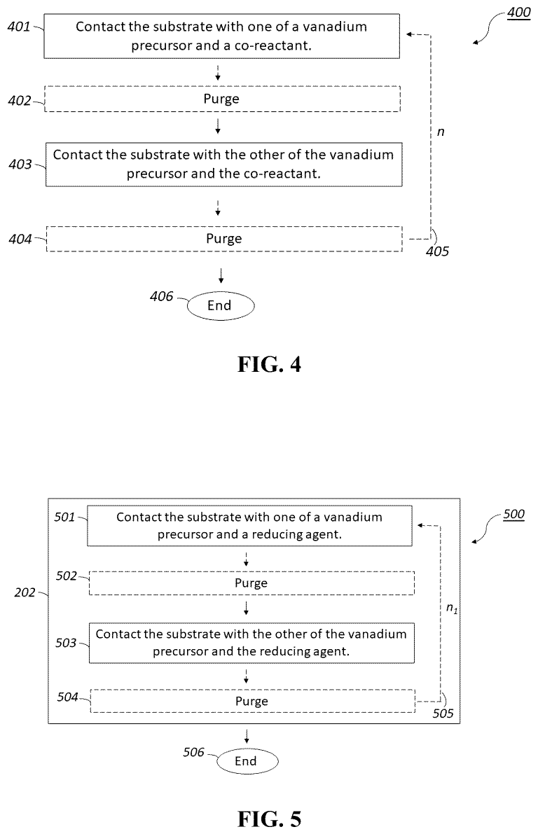

FIG. 3 is a process diagram for a method 300 for forming a structure comprising a first vanadium containing layer and a second vanadium containing layer on the surface of a substrate (e.g., see 110 in FIG. 1B) in accordance with exemplary embodiments of the disclosure. The method 300 comprises, providing a substrate in a reaction space 201 and forming a first vanadium containing layer on a surface of the substrate 202. The substrate comprising the first vanadium containing layer may optionally be annealed 203. The process steps, 202 and 203, may optionally be repeated 204 one or more x times. (Steps 201, 202, 203, and 204 are discussed above with respect to FIG. 2.) Next, a second vanadium containing layer is formed on the surface of the substrate 304. The substrate comprising the second vanadium containing layer may optionally be annealed 305. The process steps, 304 and 305, may optionally be repeated 306 one or more y times. Additionally, or alternatively, the process steps 202, 203, 304, and 305 may optionally be repeated 307 one or more z times.

As will be elaborated on below, in some embodiments, a second cyclic deposition process is used to form the second vanadium containing layer on the surface of the substrate (e.g., 304 in FIG. 3). Generally, the second cyclic deposition process comprises sequentially contacting a surface of a substrate with a vanadium precursor and a co-reactant to form the second vanadium containing layer on the surface of the substrate over the first vanadium containing layer. Additionally, or alternatively, in some embodiments, the step of forming the second vanadium containing layer on the surface of the substrate (e.g., 304 in FIG. 3) comprises continuously exposing the substrate comprising the first vanadium containing layer to a co-reactant at elevated temperature to convert at least a portion of the first vanadium containing layer to the second vanadium containing layer. In either embodiment, the co-reactant is chosen based on the target composition of the second vanadium containing layer.

In some embodiments, at least one of the one or more vanadium containing layer comprises metallic vanadium. In some embodiments, at least one of the one or more vanadium containing layer comprises vanadium in a +2 or +3 oxidation state. In some embodiments, the first vanadium containing layer comprises metallic vanadium. In some embodiments, the first vanadium containing layer comprises vanadium in a +2 or +3 oxidation state.

In some embodiments, at least one of the one or more vanadium containing layer comprises vanadium nitride. In some embodiments, at least one of the one or more vanadium containing layer is vanadium nitride. In some embodiments, the second vanadium containing layer comprises a vanadium nitride. In some embodiments, the second vanadium containing layer is a vanadium nitride.

In some embodiments, at least one of the one or more vanadium containing layers comprises a vanadium chalcogenide. In some embodiments, at least one of the one or more vanadium containing layers is a vanadium chalcogenide. In some embodiments, the second vanadium containing layer comprises a vanadium chalcogenide. In some embodiments, the second vanadium containing layer is a vanadium chalcogenide. Examples of vanadium chalcogenide include vanadium sulfide, vanadium selenide, vanadium telluride, and combinations thereof. The vanadium chalcogenide may be vanadium dichalcogenide.

At least one of the one or more vanadium containing layers deposited according to the methods disclosed herein may comprise low electrical resistivity. In some embodiments, at least one of the one or more vanadium containing layers has an electrical resistivity of less than 500 μΩ-cm at an average thickness of less than about 20 nm, or at an average thickness of less than about 10 nm, or at an average thickness of less than about 5 nm, or at an average thickness of less than about 2 nm, or even at an average thickness of less than about 1 nm. In some embodiments, at least one of the one or more vanadium containing layers has an electrical resistivity of less than 500 μΩ-cm at an average thickness of less than about 20 nm, or at an average thickness of less than about 10 nm, or at an average thickness of less than about 5 nm, or at an average thickness of less than about 2 nm, or even at an average thickness of less than about 1 nm. In some embodiments, at least one of the one or more vanadium containing layers has an electrical resistivity of less than 300 μΩ-cm at an average thickness of less than about 20 nm, or at an average thickness of less than about 10 nm, or at an average thickness of less than about 5 nm, or at an average thickness of less than about 2 nm, or even at an average thickness of less than about 1 nm. In some embodiments, at least one of the one or more vanadium containing layers has an electrical resistivity of less than 250 μΩ-cm at an average thickness of less than about 20 nm, or at an average thickness of less than about 10 nm, or at an average thickness of less than about 5 nm, or at an average thickness of less than about 2 nm, or even at an average thickness of less than about 1 nm. In some embodiments, at least one of the one or more vanadium containing layers has an electrical resistivity of less than 200 μΩ-cm at an average thickness of less than about 20 nm, or at an average thickness of less than about 10 nm, or at an average thickness of less than about 5 nm, or at an average thickness of less than about 2 nm, or even at an average thickness of less than about 1 nm. In some embodiments, at least one of the one or more vanadium containing layers has an electrical resistivity of less than 150 μΩ-cm at an average thickness of less than about 20 nm, or at an average thickness of less than about 10 nm, or at an average thickness of less than about 5 nm, or at an average thickness of less than about 2 nm, or even at an average thickness of less than about 1 nm. In some embodiments, at least one of the one or more vanadium containing layers has an electrical resistivity of less than 100 μΩ-cm at an average thickness of less than about 20 nm, or at an average thickness of less than about 10 nm, or at an average thickness of less than about 5 nm, or at an average thickness of less than about 2 nm, or even at an average thickness of less than about 1 nm. In some embodiments, at least one of the one or more vanadium containing layers has an electrical resistivity of less than 75 μΩ-cm at an average thickness of less than about 20 nm, or at an average thickness of less than about 10 nm, or at an average thickness of less than about 5 nm, or at an average thickness of less than about 2 nm, or even at an average thickness of less than about 1 nm. In some embodiments, at least one of the one or more vanadium containing layers has an electrical resistivity of less than 50 μΩ-cm at an average thickness of less than about 20 nm, or at an average thickness of less than about 10 nm, or at an average thickness of less than about 5 nm, or at an average thickness of less than about 2 nm, or even at an average thickness of less than about 1 nm. In some embodiments, at least one of the one or more vanadium containing layers of the present disclosure may have an electrical resistivity that is between about 50 μΩ-cm and about 250 μΩ-cm, or between about 75 μΩ-cm and about 200 μΩ-cm, or between about 75 μΩ-cm and about 150 μΩ-cm at an average thickness of less than about 10 nm. In some embodiments, at least one of the one or more vanadium containing layers of the present disclosure may have an electrical resistivity that is between about 50 μΩ-cm and about 250 μΩ-cm, or between about 75 μΩ-cm and about 200 μΩ-cm, or between about 75 μΩ-cm and about 150 μΩ-cm at an average thickness of less than about 5 nm. In some embodiments, at least one of the one or more vanadium containing layers of the present disclosure may have an electrical resistivity that is between about 50 μΩ-cm and about 250 μΩ-cm, or between about 75 μΩ-cm and about 200 μΩ-cm, or between about 75 μΩ-cm and about 150 μΩ-cm at an average thickness of less than about 2 nm. In some embodiments, at least one of the one or more vanadium containing layers of the present disclosure may have an electrical resistivity that is between about 50 μΩ-cm and about 250 μΩ-cm, or between about 75 μΩ-cm and about 200 μΩ-cm, or between about 75 μΩ-cm and about 150 μΩ-cm at an average thickness of less than about 1 nm. In some embodiments, the at least one vanadium containing layer is a second vanadium containing layer. In some embodiments, the at least one vanadium containing layer comprises vanadium nitride. In other embodiments, the at least one vanadium containing layer comprises a vanadium chalcogenide.

The thickness of the vanadium containing layer(s) is not particularly limited. As used herein, the “thickness” may be an average thickness measured over a defined area of the layer. Typically, the thickness of the vanadium containing layers is between about 0. 1 nm and about 100 nm, typically between about 0.1 nm and about 50 nm, or more typically between about 0.1 nm and about 10 nm. In certain embodiments, however, only a very thin layer of a vanadium containing material is desirable or allowable due to the dimensions of a semiconductor device structure. In these embodiments, the film may be continuous and uniform; or alternatively, the film may be discontinuous. In these embodiments, the average thickness of the vanadium containing layer(s) may be about 0.1 nm or more to about 5 nm or less, preferably about 0.1 nm or more to about 3 nm or less. In some embodiments, the thickness of the first vanadium containing layer is greater than the thickness of the second vanadium containing layer. Conversely, in other embodiments, the thickness of the first vanadium containing layer is less than the thickness of the second vanadium containing layer. Yet, in other embodiments, the thickness of each vanadium containing layer may be approximately the same.

In the disclosed methods for forming a structure comprising one or more vanadium containing layers, a substrate is provided in a reaction space (e.g., sec 201 in FIG. 2 and FIG. 3). In other words, a substrate is brought into a space where the deposition conditions can be controlled. The substrate is not particularly limited and is discussed above. The reaction space may be a reaction chamber or reaction chambers in a deposition assembly, for example a semiconductor processing apparatus. The reaction space may be a reaction chamber or reaction chambers in a cluster tool in which different processes are performed to form an integrated circuit. In some embodiments, the reaction space may be a reaction chamber or reaction chambers in a flow-type reactor, such as a cross-flow reactor. In some embodiments, the reaction space may be a reaction chamber or reaction chambers in a showerhead reactor. In some embodiments, the reaction space may be a reaction chamber or reaction chambers in a space-divided reactor. In some embodiments, the reaction space may be a reaction chamber or reaction chambers in a single wafer ALD reactor. In some embodiments, the reaction space may be a reaction chamber or reaction chambers in a high-volume manufacturing single wafer ALD reactor. In some embodiments, the reaction space may be a reaction chamber or reaction chambers in a batch reactor for processing multiple substrates simultaneously.

In some embodiments, the step of providing a substrate in a reaction space 201 further comprises maintaining a temperature of the substrate and/or a temperature of the reaction space at an elevated temperature (i.e., above room temperature). For instance, the substrate may be maintained at an elevated temperature. In some embodiments, the substrate may be maintained at a first temperature during a first deposition process and a second temperature during a second deposition process, and even a third temperature or range of temperatures during other process steps. The temperature of the substrate may be optimized to tune or maximize the deposition process(es) on the substrate surface. In some embodiments, the method further comprises heating the substrate to a temperature of at least about 40° C. to no more than about 600° C. In some embodiments, the method comprises maintaining the substrate temperature from about 40° C. to about 600° C., typically from about 100° C. to about 500° C., or from about 100° C. to about 450° C., or from about 100° C. to about 425° C., or from about 100° C. to about 400° C., or from about 100° C. to about 375° C., or from about 100° C. to about 350° C., or from about 100° C. to about 325° C., or from about 100° C. to about 300° C., or from about 100° C. to about 275° C., or from about 100° C. to about 250° C., or from about 200° C. to about 450° C., or from about 200° C. to about 425° C., or from about 200° C. to about 400° C., or from about 200° C. to about 375° C., or from about 200° C. to about 350° C. In some embodiments, the method further comprises heating the substrate to a temperature of less than about 450° C., or less than about 425° C., or less than about 400° C., or less than about 375° C., or less than about 350° C., or less than about 325° C., or less than about 300° C., or less than about 275° C., or less than about 250° C. In some embodiments, the method comprises maintaining the substrate temperature at about 100° C., or at about 125° C., or at about 150° C., or at about 175° C., or at about 200°° C., or at about 225° C., or at about 250° C., or at about 275° C., or at about 300° C., or at about 325° C., or at about 350° C., or at about 375° C., or at about 400° C., or at about 425° C., or at about 450° C., or at about 475° C., or at about 500° C., or at about 525° C., or at about 550° C.

In some embodiments, the step of providing a substrate in a reaction space 201 further comprises controlling a pressure within the reaction space. In some embodiments, the substrate may be maintained at a first pressure during a first deposition process and a second pressure during a second deposition process, and even a third pressuring during other process steps. The pressure within the reaction space may be between about 1 mTorr and about 760 Torr, typically between about 0.5 Torr and about 100 Torr, such as about 10 Torr, or about 15 Torr, or about 20 Torr, or about 30 Torr, or about 40 Torr, or about 50 Torr. In some embodiments, a pressure within the reaction space during the cyclic deposition process is less than about 500 Torr, or a pressure within the reaction space during the cyclic deposition process is between about 0.1 Torr and about 500 Torr, or between about 1 Torr and about 100 Torr, or between about 1 Torr and about 50 Torr, or between about 1 Torr and about 20 Torr. In some embodiments, a pressure within the reaction space during the cyclic deposition process is less than about 200 Torr, or less than about 100 Torr, or less than about 50 Torr, or less than about 20 Torr, or less than about 10 Torr.

In embodiments, a first vanadium containing layer is deposited on the surface of the substrate (e.g., sec 202 FIG. 2 and FIG. 3). The first vanadium containing layer is formed on the surface of the substrate using a cyclic deposition process. Further, in some embodiments, a second vanadium containing layer is formed on the surface of the substrate (e.g., see 304 in FIG. 3). In some of these embodiments, the second vanadium containing layer is also formed using a cyclic deposition process. Generally, the one or more deposition processes comprises sequentially contacting a surface of a substrate with a vanadium precursor and a co-reactant to form a vanadium containing layer on the surface. Suitable vapor deposition methods include ALD and cyclic CVD, including plasma-enhanced, and thermal methods. The selection of the vanadium precursor and the co-reactant is chosen based deposition process and on the target composition of the vanadium containing film.

An exemplary embodiment of a cyclic deposition process is shown in FIG. 4. The cyclic deposition process 400 comprises, contacting a surface of the substrate with one of a vanadium precursor and a co-reactant 401; and contacting the surface of the substrate with the other of the vanadium precursor and the co-reactant 403, thereby forming a vanadium containing layer on the surface of the substrate. For example, the surface of the substrate may be contacted with the vanadium precursor, then contacted with the co-reactant. Additionally, or alternatively, the surface of the substrate may be contacted with the reducing agent, then contacted with the co-reactant. The method may further comprise, purging the reaction space (402 and 404) between the contacting steps. Steps 401 and 403, with the optional purging steps 402 and 404, make up one deposition cycle. The method may further comprise repeating the deposition cycle one or more (n) times 405 in a cyclic deposition process to increase the uniformity and/or the thickness of the vanadium containing layer on the surface of the substrate. The cyclic deposition process may be terminated 406 once the desired uniformity and/or thickness of the vanadium containing layer has been reached.

In the methods disclosed herein, the surface of the substrate is sequentially exposed to a vanadium precursor and a co-reactant, 401 or 403. More specifically, the vanadium precursor is introduced into the reaction space in vapor form and the surface of the substrate is contacted with the vanadium precursor. Likewise, the co-reactant is introduced into the reaction space in vapor form and the surface of the substrate is contacted with the co-reactant. Hence, the vanadium precursor and the co-reactant should have sufficient vapor pressure such that they can be introduced into the reaction space and transported to the substrate surface in vapor form. The vanadium precursor and/or the co-reactant may be heated to provide sufficient vapor pressure (typically between 1-20 torr) and/or entrained in a flow of an inert carrier gas (e.g., nitrogen and/or a noble gas such as helium (He) and argon (Ar)) and introduced into the reaction space.

In some embodiments, the step of introducing the vanadium precursor into the reaction space comprises pulsing the vanadium precursor over the substrate surface. In some embodiments, the step of introducing the co-reactant into the reaction space comprises pulsing the co-reactant over the substrate surface. In embodiments, where the vanadium precursor and/or the co-reactant are pulsed over the substrate surface, the pulse time may be between about 0.01 second and about 60 seconds, or from about 0.1 second to about 30 seconds, or from about 1 second to about 10 seconds. During the pulsing, the flow rate of the vanadium precursor and/or the co-reactant may be less than about 2000 sccm, or less than about 1000 sccm, or less than about 500 sccm, or less than about 100 sccm. The flow rate may be, for example, from about 500 sccm to about 1200 sccm, such as about 600 sccm, or about 800 sccm, or about 1000 sccm. The pulse time may vary according to the vanadium precursor or the co-reactant in question, the configuration of the reaction chamber, and other process parameters (e.g., temperature, pressure, substrate, etc.), which may independently be selected to optimize the deposition according to the application in question.

In some embodiments, the step of providing of the vanadium precursor into the reaction space and the step of providing the co-reactant into the reaction space at least partially at overlap. For instance, in some embodiments where the vanadium precursor and the co-reactant are pulsed over the substrate surface, the vanadium precursor pulse and the co-reactant pulse may at least partially overlap. In some embodiments, the introduction of the vanadium precursor and the introduction of the co-reactant into the reaction space may be simultaneous. In some embodiments, the introduction of vanadium precursor and the introduction the co-reactant into the reaction space may be at least partially separate. For instance, in some embodiments where the vanadium precursor and the co-reactant are pulsed over the substrate surface, the vanadium precursor pulse and the co-reactant pulse may at least be partially separated. In some embodiments, the introduction of the vanadium precursor and the introduction of the co-reactant into the reaction space may be completely separate. For instance, in some embodiments where the vanadium precursor and the co-reactant are pulsed over the substrate surface, the vanadium precursor pulse and the co-reactant pulse may be completely separate. In some embodiments, the reaction space is purged between providing the vanadium precursor to the co-reactant and providing the co-reactant to the reaction space. For example, optional purging steps are shown in 402 and 404 in FIG. 4.

In some embodiments, the step of introducing the vanadium precursor into the reaction space and/or the step of introducing the co-reactant into the reaction space occurs in oxygen deficient or oxygen free environment. To help ensure a low oxygen concentration in the reaction space, one or both of the vanadium precursor and the co-reactant have a low oxygen impurity concentration (e.g., less than 1,000 ppm, or less than 100 ppm, or less than 10 ppm, or less than 1 ppm, or less than 100 ppb). Further, if applicable, high purity carrier gasses and other gasses are used. The precursor, the co-reactant, carrier gasses, and other gasses each may be passed through a gas purifier prior to entering the reaction space to remove oxygen impurities, such as water and oxygen, from the vapor flow. In some embodiments, the step of introducing the vanadium precursor into the reaction space and/or the step of introducing the co-reactant into the reaction space occurs in a reducing environment. For example, one or both of the steps of introducing the vanadium precursor into the reaction space and/or the step of introducing the co-reactant into the reaction space may occur while co-flowing hydrogen gas.

In accordance with some embodiments of the disclosure, the cyclic deposition process 400 is a thermal deposition process. In thermal deposition, the chemical reactions are promoted by increasing the temperature of the substrate relevant to ambient temperature. Generally, the temperature increase provides the energy needed for the formation of the vanadium containing layer in the absence of other external energy sources, such as plasma, radicals, or other forms of radiation. In these embodiments, the deposition process does not include use of a plasma to form activated species for use in the deposition process. For example, the cyclic deposition process may not comprise the use of plasma, may not comprise the formation or use of excited species, and/or may not comprise the formation or use of radicals in any of the process steps.

In accordance with other embodiments of the disclosure, the cyclic deposition process 400 is partly or completely a plasma-enhanced process. In other words, at least one process step in the cyclic deposition process uses a plasma to excite one or more precursors, one or more reactants, and/or one or more inert gases. For example, one or more of the vanadium precursor, the co-reactant, and an inert gas may be supplied through a plasma source to form excited or activated species. The plasma may be a direct plasma or a remote plasma. In some embodiments, the power for generating the plasma is from about 10 W to about 2,000 W, typically from about 20 W to about 1,000 W, or from about 20 W to about 500 W. The plasma may be generated in the reaction space, near the substrate surface; or the plasma may be generated up stream of the reaction space in a remote location.

The various process steps shown in FIG. 4 may be repeated 405 one or more times to grow a vanadium containing layer having a target thickness and/or degree of uniformity on the surface of the substrate. For example, the method may comprise repeating steps 401 and 403 one or more (n) times, or repeating steps 401, 402, 403, and 404 one or more (n) times, to form a vanadium containing layer having a targeted thickness and/or degree of uniformity on the surface of the substrate. In any of these embodiments, other pulse sequences are possible. For example, the substrate may be exposed to two or more pulses of the vanadium precursor, then exposed to the co-reactant; or conversely, the substrate may be exposed to two or more pulses of the co-reactant, then exposed to the vanadium precursor.

The number of repeated cycles (n) is not particularly limited and depends on the growth per-cycle (GPC) rate of the vanadium containing layer and the targeted thickness and/or degree of uniformity of the layer. The GPC of the vanadium containing layer may be less 3 Å/cycle, between about 0.01 and 3 Å/cycle, or between about 0.05 to about 2 Å /cycle, or between about 0.05 Å/cycle to 1 Å/cycle. The number of repeated cycles (n) may be between 1 and about 1,000, typically between 1 and about 500, or between 1 and about 200, or between 1 and about 100, or between 1 and about 50, or between 1 and about 10.

The specific process conditions described above for forming a vanadium containing layer may be chosen by one of skill on the art to optimize the deposition of the vanadium containing layer. The specific combination of process may vary depending upon the composition of the vanadium containing layer. In particular, the precursor and co-reactant is selected based upon the target composition of the vanadium containing layer. Further, as will be appreciated by one of skill in the art, a number of process parameters may impact the growth rate of the film and the quality the film (e.g., uniformity, conformality, and electrical properties). These process parameters include, but are not limited to, the temperature of the substrate and the pressure of the reaction space during the deposition process, the duration of the purge steps (if any), the plasma power (if applicable), and the purity of the precursors, co-reactants, and other gasses. Optimization of these parameters to obtained improved growth rates and film properties can be achieved based on routine work and such optimization is within the capabilities of one of skill in the art.

In some embodiments, the cyclic deposition process described above is a first cyclic deposition process, which may be used to form first vanadium containing layer (e.g., see 202 in FIG. 2 and FIG. 3). FIG. 5 shows an embodiment of a first cyclic deposition process for forming the form first vanadium containing layer. (The process steps in FIG. 5 are also shown in FIG. 4 and described above, but the co-reactant is a reducing agent.) The cyclic deposition process 500 comprises, contacting a surface of the substrate with one of a vanadium precursor and a reducing agent 501; and contacting the surface of the substrate with the other of the vanadium precursor and the reducing agent 503, thereby forming a first vanadium containing layer on the surface of the substrate. For example, the surface of the substrate may be contacted with the vanadium precursor, then contacted with the reducing agent. Additionally, or alternatively, the surface of the substrate may be contacted with the reducing agent, then contacted with the vanadium precursor. The method may further comprise, optionally purging the reaction space (502 and 504) between the contacting steps. Steps 501 and 503, with the optional purging steps 502 and 504, make up one deposition cycle. The method may further comprise repeating the deposition cycle one or more (n₁) times 505 in a cyclic deposition process to increase the uniformity and/or the thickness of the first vanadium containing layer on the surface of the substrate. The first cyclic deposition process may be terminated 506 once the desired uniformity and/or thickness of the first vanadium containing layer has been reached.

The vanadium precursor is a chemical compound that comprises vanadium. The vanadium precursor may be an inorganic compound, or it may be an organic compound. Example vanadium precursors include, but are not limited to, a vanadium halide, a vanadium β-diketonate, a vanadium amidinate, a vanadium alkoxide, a vanadyl alkoxide, a vanadium alkylamido, and a vanadium cyclopentadienyl. The vanadium precursor may have a mixture of ligand types. For example, the vanadium precursor may comprise a β-diketonate ligand and one or more halide ligands. In some embodiments, the vanadium precursor comprises a vanadium β-diketonate compound. A β-diketonate ligand has a general structure of RC(O)C(R)C(O)R where each R is an independently selected substituent, typically selected from a hydrogen, an alkyl group, an alkyl halide group, an aryl group, an aryl halide group, an alkenyl group, an alkynyl group, an alkylsilyl group, and a halogen. In some embodiments, the vanadium precursor comprises a vanadium halide, such as, for example, one or more of vanadium fluoride, vanadium chloride, vanadium bromide, vanadium iodide, vanadium oxyfluoride, vanadium oxychloride, vanadium oxybromide, and vanadium oxyiodide. In some preferred embodiments, the vanadium precursor is vanadium tetrachloride (VCl₄) or vanadium oxytrichloride (VOCl₃).

The reducing agent is a chemical compound that at least partially reduces the vanadium precursor. As a result, in some embodiments, the oxidation state of vanadium in the vanadium containing layer may be lower than the oxidation state of vanadium in the vanadium precursor. Reduction of the vanadium precursor may occur on or near the surface of the substrate. Without wishing to be bound to a particular mechanism, the reducing agent may contact the substrate comprising a chemisorbed vanadium precursor and the reducing agent may at least partially reduce the chemisorbed vanadium precursor. Additionally, or alternatively, in some embodiments, reduction of the vanadium precursor may occur at least partially in the gas phase. In preferred embodiments, the reducing agent comprises indium. In some embodiments, the reducing agent is an organoindium compound. In some embodiments, the reducing agent does not contain oxygen. In some embodiments, the reducing agent does not contain nitrogen. In some embodiments, the reducing agent does not contain a halogen. In some embodiments, the reducing agent comprises an alkylindium compound, such as, for example, trimethylindium (In(CH₃)₃); abbreviated as TMI), tricthylindium (In(C₂H₅)₃), tri-isopropylindium (In(i-C₃H₇)₃), and tri-tertbutylindium (In(t-C₄H₉)₃). In some embodiments, the reducing agent is trimethylindium.

The cyclic deposition process shown in FIG. 5 may comprise other process steps that are not explicitly shown. For example, in some of these embodiments, the cyclic deposition process further comprises optionally introducing a flow of hydrogen into the reaction space during one or both of the contacting the surface of the substrate the vanadium precursor and the contacting the surface of the substrate the reducing agent. In this regard, hydrogen gas may be co-introduced into the reaction chamber with one or both of the vanadium precursor or the reducing agent.

In some embodiments, the cyclic deposition process described above is a second cyclic deposition process, which may be used to form second vanadium containing layer (e.g., see 304 in FIG. 3). In some of these embodiments, the second vanadium containing layer comprises vanadium nitride. FIG. 6 shows an embodiment of a second cyclic deposition process for forming a vanadium nitride layer. (The process steps in FIG. 6 are also shown in FIG. 4 and described above, but the co-reactant is a nitrogen reactant.) The cyclic deposition process 600 comprises, contacting a surface of the substrate with one of a vanadium precursor and a nitrogen reactant 601; and contacting the surface of the substrate with the other of the vanadium precursor and the nitrogen reactant 603, thereby forming a vanadium nitride layer on the surface of the substrate. For example, the surface of the substrate may be contacted with the vanadium precursor, then contacted with the nitrogen reactant. Additionally, or alternatively, the surface of the substrate may be contacted with the nitrogen reactant, then contacted with the vanadium precursor. The method may further comprise, optionally purging the reaction space (602 and 604) between the contacting steps. Steps 601 and 603, with the optional purging steps 602 and 604, make up one deposition cycle. The method may further comprise repeating the deposition cycle one or more (n₂) times 605 in a cyclic deposition process to increase the uniformity and/or the thickness of the vanadium nitride layer on the surface of the substrate. The second cyclic deposition process may be terminated 606 once the desired uniformity and/or thickness of the vanadium nitride layer has been reached.

The vanadium precursor is described above. In some embodiments, the vanadium precursor used in the second cyclic deposition process to form a vanadium nitride layer is chemically distinct from the vanadium precursor that is used in the first cyclic deposition process to form the first vanadium containing layer. In this context, the vanadium precursor that is used in the first cyclic deposition process is a first vanadium precursor and the vanadium precursor that is used in the second cyclic deposition process is a second vanadium precursor. In other preferred embodiments, the vanadium precursors utilized in the two cyclic deposition processes are the same chemical compound. In other words, the first vanadium precursor and the second vanadium precursor are the same chemical compounds. In some embodiments, the vanadium precursor comprises a vanadium halide, such as, for example, one or more of vanadium fluoride, vanadium chloride, vanadium bromide, vanadium iodide, vanadium oxyfluoride, vanadium oxychloride, vanadium oxybromide, and vanadium oxyiodide. In preferred embodiments, the vanadium precursor is vanadium tetrachloride (VCl₄) or vanadium oxytrichloride (VOCl₃).

The nitrogen reactant is a compound that comprises nitrogen. In some embodiments, the nitrogen reactant comprises one or more of ammonia (NH₃), an alkyl amino (NR₃, where each R is independently an H, an alkyl group, or an aryl group), hydrazine (N₂H₄), and a substituted hydrazine. In some embodiments, the nitrogen reactant comprises a nitrogen plasma species. In some embodiments, a plasma may be generated from a reactive gas comprising a nitrogen compound and a nitrogen co-reactant is formed in or it is otherwise present in the plasma discharge. In some embodiments, the reactive gas comprises one or more of nitrogen (N₂), a N₂/H₂ mixture, ammonia (NH₃), an alkyl amino (NR₃, where each R is independently an H, an alkyl group, or an aryl group), hydrazine (N₂H₄), and a substituted hydrazine; hence, the co-reactant may comprise one or more of N₂, NH₃, an alkyl amino, hydrazine N₂H₄, a substituted hydrazine, as applicable, as well as excited species, radical species, and plasma species formed therefrom. In some embodiments, the nitrogen co-reactant comprises a nitrogen plasma species, for example, the nitrogen co-reactant may comprise one or more of activated nitrogen (N₂), activated ammonia (NH₃), nitrogen atoms (N), NH and NH₂ radicals, and other N—H containing species created in the plasma discharge. In some embodiments, the nitrogen co-reactant is a nitrogen plasma species; by way of non-limiting example, the nitrogen co-reactant may be one or more of activated nitrogen (N₂), activated ammonia (NH₃), nitrogen atoms (N), NH and NH₂ radicals, and other N—H containing species created in the plasma discharge.

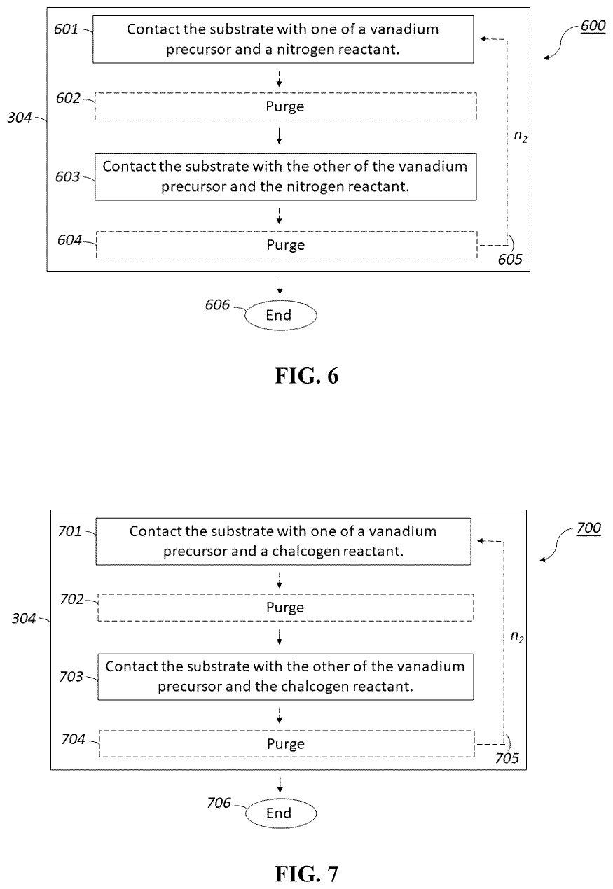

In some embodiments, the cyclic deposition process described above is a second cyclic deposition process, which may be used to form second vanadium containing layer (e.g., see 304 in FIG. 3). In some of these embodiments, the second vanadium containing layer comprises a vanadium chalcogenide, such as, for examples, one or more of vanadium sulfide, vanadium selenide, and vanadium telluride. FIG. 7 shows an embodiment of a second cyclic deposition process for forming a vanadium chalcogenide layer. (The process steps in FIG. 7 are also shown in FIG. 4 and described above, but the co-reactant is a chalcogen reactant.) The cyclic deposition process 700 comprises, contacting a surface of the substrate with one of a vanadium precursor and a nitrogen reactant 701; and contacting the surface of the substrate with the other of the vanadium precursor and the chalcogen reactant 703, thereby forming a vanadium chalcogenide layer on the surface of the substrate. For example, the surface of the substrate may be contacted with the vanadium precursor, then contacted with the chalcogen reactant. Additionally, or alternatively, the surface of the substrate may be contacted with the chalcogen reactant, then contacted with the vanadium precursor. The method may further comprise, optionally purging the reaction space (702 and 704) between the contacting steps. Steps 701 and 703, with the optional purging steps 702 and 704, make up one deposition cycle. The method may further comprise repeating the deposition cycle one or more (n₂) times 705 in a cyclic deposition process to increase the uniformity and/or the thickness of the vanadium chalcogenide layer on the surface of the substrate. The second cyclic deposition process may be terminated 706 once the desired uniformity and/or thickness of the vanadium chalcogenide layer has been reached.

The vanadium precursor is described above. In some embodiments, the vanadium precursor used in the second cyclic deposition process to form a vanadium chalcogenide layer is chemically distinct from the vanadium precursor that is used in the first cyclic deposition process to form the first vanadium containing layer. In this context, the vanadium precursor that is used in the first cyclic deposition process is a first vanadium precursor and the vanadium precursor that is used in the second cyclic deposition process is a second vanadium precursor. In other preferred embodiments, the vanadium precursors utilized in the two cyclic deposition processes are the same chemical compound. In other words, the first vanadium precursor and the second vanadium precursor are the same chemical compounds. In some embodiments, the vanadium precursor comprises a vanadium halide, such as, for example, one or more of vanadium fluoride, vanadium chloride, vanadium bromide, vanadium iodide, vanadium oxyfluoride, vanadium oxychloride, vanadium oxybromide, and vanadium oxyiodide. In preferred embodiments, the vanadium precursor is vanadium tetrachloride (VCl₄) or vanadium oxytrichloride (VOCl₃).

The chalcogen reactant is a compound that comprises chalcogen. In some embodiments, the chalcogen reactant comprises a chalcogen plasma species. In some of these embodiments, the chalcogen reactant comprises one or more of elemental sulfur, selenium, and tellurium. Suitable chalcogen reactants comprising sulfur include, but are not limited to, elemental sulfur, hydrogen sulfide (H₂S), dimethyl sulfide ((CH₃)₂S), dimethyl disulfide ((CH₃)₂S₂), diphenyl sulfide ((C₆H₅)₂S), diphenyl disulfide ((C₆H₅)₂S₂), ammonium sulfide ((NH₄)₂S), dimethyl sulfoxide ((CH₃)₂SO), and plasma species comprising sulfur generated therefrom. Suitable chalcogen reactants comprising selenium include, but are not limited to, elemental selenium, hydrogen selenide (H₂Se), dimethyl selenide ((CH₃)₂Se), dimethyl diselenide ((CH₃)₂Se₂), diphenyl selenide ((C₆H₅)₂Se), diphenyl diselenide ((C₆H₅)₂Se₂), and plasma species comprising selenium generated therefrom. Suitable chalcogen reactants comprising tellurium include, but are not limited to, elemental tellurium, hydrogen telluride (H₂Te), dimethyl telluride ((CH₃)₂Te), diphenyl ditelluride ((C₆H₅)₂Te₂), and plasma species comprising tellurium generated therefrom. The formation of chalcogen containing plasma species, such as, excited chalcogen reactants, chalcogen atoms, and chalcogen radicals, may be generated from a reactive gas comprising a chalcogen by passing a chalcogen containing reactant gas and optionally an inert gas (e.g., He, Ar, etc.) through a plasma generator. In some of these embodiments, the plasma is free of oxygen species. In some of these embodiments, the plasma is free of nitrogen species.

In other embodiments, the step of forming the second vanadium containing layer (e.g., sec 304 in FIG. 3) comprises exposing the substrate comprising the first vanadium containing layer to a co-reactant for a set period of time at elevated temperature to convert at least a portion of the first vanadium containing layer to the second vanadium containing layer. The co-reactant may be introduced into the reaction space in a continuous manner, or it may be pulsed into the reaction space. In either case, the co-reactant may react with the vanadium containing layer to convert at least a portion of the vanadium containing layer to the second vanadium containing material. In some embodiments, a flow of hydrogen gas may be co-introduced into the reactor with the co-reactant. In some embodiments, the formation of the second vanadium containing layer occurs via thermal process. In other embodiments, the formation of the second vanadium containing layer occurs via plasma-based process. The power for generating the plasma can be varied in different embodiments of the disclosure. In some embodiments, the power for generating the plasma is from about 10 W to about 2,000 W, typically from about 20 W to about 1,000 W, or from about 20 W to about 500 W. In either of these embodiments, during the contacting of the surface with the co-reactant, the substrate may be heated to a temperature that is from about 40° C. to about 1,000° C., typically from about 100° C. to about 600° C., typically from about 100° C. to about 550° C., or typically from about 100° C. to about 500° C., or from about 100° C. to about 450° C., or from about 100° C. to about 425° C., or from about 100° C. to about 400° C., or from about 100° C. to about 375° C., or from about 100° C. to about 350° C., or from about 100° C. to about 325° C., or from about 100° C. to about 200° C., or from about 100° C. to about 275° C., or from about 100° C. to about 250° C., or from about 200° C. to about 450° C., or from about 200° C. to about 425° C., or from about 200° C. to about 400° C., or from about 200° C. to about 375° C., or from about 200° C. to about 350° C. In some embodiments, the step of heating the substrate while flowing a co-reactant may be performed for a period of less than an hour, or less than 30 minutes, or less than 15 minutes, or less than 5 minutes, or even less than 1 minute.

In some embodiments, the substrate comprising the first vanadium containing layer is contacted with a nitrogen reactant to convert at least a portion of the vanadium containing layer to vanadium nitride. In some of these embodiments, the substrate comprising the first vanadium containing layer may be annealed under a nitriding environment. For instance, the substrate may be annealed while flowing NH₃ and/or a forming gas over the substrate surface. In other of these embodiments, the formation of the vanadium nitride layer occurs via plasma-based process. For instance, the nitrogen reactant may comprise a plasma species such as, for example, one or more of activated nitrogen, activated ammonia, nitrogen atoms, NH radicals, NH₂ radicals, and combinations thereof.

In some embodiments, the substrate comprising the first vanadium containing layer is contacted with a chalcogen reactant to convert at least a portion of the vanadium containing layer to a vanadium chalcogenide. In some of these embodiments, the substrate comprising the first vanadium containing layer may be annealed in a chalcogenide-forming environment, for example while flowing a chalcogen reactant over the substrate surface. For instance, the substrate may be annealed while flowing one or more of hydrogen sulfide (H₂S), hydrogen selenide (H₂Se), and hydrogen telluride (H₂Te) over the substrate surface. Other suitable chalcogen reactants comprising sulfur include, but are not limited to, elemental sulfur, dimethyl sulfide ((CH₃)₂S), dimethyl disulfide ((CH₃)₂S₂), diphenyl sulfide ((C₆H₅)₂S), diphenyl disulfide ((C₆H₅)₂S₂), ammonium sulfide ((NH₄)₂S), and dimethyl sulfoxide ((CH₃)₂SO). Other suitable chalcogen reactants comprising selenium include, but are not limited to, elemental selenium, dimethyl selenide ((CH₃)₂Se), dimethyl diselenide ((CH₃)₂Se₂), diphenyl selenide ((C₆H₅)₂Se), and diphenyl diselenide ((C₆H₅)₂Se₂). Other suitable chalcogen reactants comprising tellurium include, but are not limited to, elemental tellurium, dimethyl telluride ((CH₃)₂Te), and diphenyl ditelluride ((C₆H₅)₂Te₂). In other of these embodiments, the formation of the vanadium chalcogenide layer occurs via plasma-based process. For instance, the chalcogenide reactant may comprise a plasma species such as, for example, one or more of activated chalcogen species, chalcogen atoms, chalcogen radicals, and combinations thereof. In some of these embodiments, the chalcogen reactant is free of oxygen and the plasma is free of oxygen species. In some of these embodiments, the chalcogen reactant is free of nitrogen and the plasma is free of nitrogen species.

Referring to FIG. 3, in certain embodiments, the step of forming the first vanadium containing layer 202 and the step of forming the second vanadium containing layer 304 may be repeated 307 one or more z times. As an example, a first vanadium containing layer maybe be formed on a surface of a substrate using a cyclic deposition process as described above (e.g., see FIG. 5), then the second vanadium containing layer maybe formed on the surface of the substrate from the first vanadium containing layer. This process may be repeated one or more z times to increase the thickness of the second vanadium containing layer.

In some embodiments, the method for forming a structure comprising one or more vanadium containing layers further comprises optionally annealing the substrate comprising the one or more vanadium containing layers (e.g., see 203 in FIG. 2 and FIGS. 3 and 305 in FIG. 3). In certain embodiments, where a second vanadium containing layer is formed using a second cyclic deposition process as described above, one or more optional annealing steps may be performed before and/or after the second cyclic deposition process. In certain other embodiments, where a second vanadium containing layer is formed in an annealing step as described above, one or more additional annealing steps may optionally be performed before and/or after the annealing step to for the second vanadium containing layer. Annealing may be performed by heating the substrate comprising the vanadium containing layer to an annealing temperature of at least about 300° C. to no more than about 1200° C. for a set period of time, typically at least about 400° C. to no more than about 600° C. The annealing may be performed at a reduced pressure. Additionally, or alternatively, the annealing may be performed in one or more of an inert environment (e.g., by flowing one or more of He, Ar, and N₂ into the space), a reducing environment (e.g., by flowing H₂ into the reaction space), and a nitriding environment (e.g., by flowing NH₃ and/or forming gas into the reaction space). The length of time of the anneal step may vary greatly, ranging from tenths of a second to hours, typically from minutes to hours. Further, more than one annealing step may be performed. An annealing step or multiple annealing steps may be performed to remove impurities in the layer, for example to reduce the carbon content of the layer, improve the oxygen resistance of the film, improve the layer uniformity, to alter the morphology of the layer and/or to alter the composition of the layer.

Another aspect of the present disclosure relates to systems for forming the one or more vanadium containing layers and the structures disclosed herein, using the methods disclosed herein. In some embodiments, the system is a vapor deposition assembly, for example a semiconductor processing apparatus, that comprises a reaction space (i.e., at least one reaction chamber) for accommodating a substrate. The deposition assembly may comprise one reaction chamber, two reaction chambers, three reaction chambers, four reaction chambers, or more. In some embodiments, the step of forming a first vanadium layer (e.g., see 202 in FIG. 2 and FIG. 3) occurs in a first reaction chamber, and the step of forming a second vanadium containing layer (e.g., see 304 FIG. 3) occurs in a second reaction chamber. In some embodiments, the step of forming a first vanadium layer (e.g., see 202 in FIG. 2 and FIG. 3) and the step of forming a second vanadium containing layer (e.g., see 304 FIG. 3) occurs in the same reaction chamber. In either case, optional annealing steps (e.g., see 203 in FIG. 2 and FIGS. 3 and 305 in FIG. 3) may occur in the same or different reaction chambers. In some embodiments, deposition assembly is a cluster tool. In some embodiments, a reaction chamber or reaction chambers in a flow-type reactor may be utilized. In some embodiments, a reaction chamber or reaction chambers in a showerhead-type reactor may be utilized. In some embodiments, a reaction chamber or reaction chambers in a space divided reactor may be utilized. In some embodiments, a reaction chamber or reaction chambers in a high-volume manufacturing- capable single wafer reactor may be utilized. In other embodiments, a reaction chamber or reaction chambers in a batch reactor may be utilized.

The vapor deposition assembly comprises a means for contacting a surface of the substrate with at least one vanadium precursor, at least one reducing agent, and optionally at least one co-reactant. In this regard, the deposition assembly may comprise a reactant injector system that comprises at least one vessel comprising the vanadium precursor, at least one vessel comprising the reducing agent, and optionally at least one vessel comprising the co-reactant. The deposition assembly may further comprise a means for purging the reaction space between the various contacting steps, and optionally a means for generating a plasma. The vanadium precursor, the reducing agent, and the co-reactant as well as the other elements are described above.

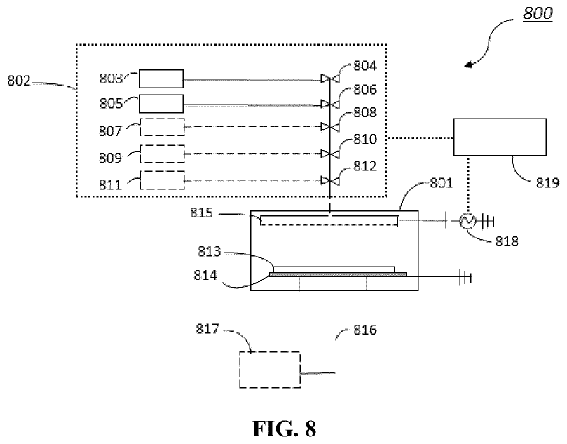

FIG. 8 shows a schematic diagram of an exemplary embodiment of a vapor deposition assembly 800 according to the present disclosure. The various precursors and reactants are provided into a reaction chamber 801 through an injector system 802. The injector system 802 is configured to provide a vanadium precursor in gaseous form from a vanadium precursor source 803 that is in gas communication with the reaction chamber 801 via a vanadium precursor source valve 804 and a reducing agent in gaseous form from a reducing agent source 805 that is in gas communication with the reaction chamber 801 via a reducing agent source valve 806. The injector system 802 may further be configured to provide an optional co-reactant in gaseous form from a co-reactant source 807 that is in gas communication with the reaction chamber 801 via a co-reactant source valve 808. The injector system 802 may further comprise one or more other precursors, reactants, and/or other gases (e.g., purge gasses and carrier gasses, etc.) from other sources (e.g., 809 and 811) that are in gas communication with the reaction chamber 801 (e.g., via valves 810 and 812) to the reaction chamber 801. The injector system 802 may further comprise a means for heating the vanadium precursor source 803, the reducing agent source 805, the optional co-reactant source 807, and the other gas sources 809 and 811, as well as the corresponding valves (804, 806, 808, 810, and 812) and gas lines (not shown), if required, to facilitate the introduction of the various precursors, reactants, and other gases into the reaction chamber 801. The various gasses flow into the reaction chamber 801 though a showerhead 815 that is positioned over a substrate 813 positioned on a susceptor 814. In FIG. 8 the various gasses flow into the reaction chamber 801 from the top of the chamber above the substrate 813 through a showerhead 815; however, one of skill in the art will recognize that other flow configurations and/or other mechanisms for housing the substrate may be utilized. In some embodiments, the reaction chamber 801 further comprises one or more heating elements (not shown) that are in thermal communication with the substrate 813 and one or more thermocouples (not shown), to measure and maintain a temperature of the substrate 813 at set temperatures. Unreacted gasses and gaseous reaction by-products exit the reaction chamber 801 through an exhaust line 816 that is optionally coupled to one or more vacuum pumps 817.

In some embodiments, the vapor deposition assembly 800 further comprises an optional plasma generator 818 (e.g., a RF power generator or microwave power generator). In FIG. 8, the plasma generator 818 is electrically connected to the showerhead 815, allowing for the showerhead 815 to be biased relative to the susceptor 814 to form a plasma discharge between the two. As will be appreciated by one of skill in the art, other configurations for generating a plasma are possible. For instance, in some embodiments, a remote plasma unit may be positioned upstream of the reaction chamber 801 such that plasma species may be introduced into the reaction chamber.

The deposition assembly 800 also comprises a controller 819 operably connected to the components of the injector system 802, for example, the various valves, 804, 806, 808, 810, 812, and other components (not shown) and the optional plasma generator 818. The controller 819 is configured and programmed to independently control (e.g., turn on and off, etc.) the supply of the various gasses (e.g., the vanadium precursor, the reducing agent, the optional co-reactant, and the optional other gasses, etc.), the optional plasma generator 818, and other components, as required, to form one or more vanadium containing layers on a surface of the substrate 813.

In some embodiments, the controller 819 is configured and programed to perform at least one deposition cycle of a (first) cyclic deposition process for forming a (first) vanadium containing layer (for example, the process according to FIG. 5). The controller 819 may be configured and programed to perform a first operation and a second operation, among other things. In the first operation, the controller 819 opens the vanadium precursor source valve 804 to flow the vanadium precursor from the vanadium precursor source 803 into the reaction chamber 801, thereby exposing a surface of the substrate 813 to the vanadium precursor and, after a set period of time, the controller 819 closes the vanadium precursor source valve 804 to cease the flow of the vanadium precursor into the reaction chamber 801. In the second operation, the controller 819 opens the reducing agent source valve 806 to flow the reducing agent from the reducing agent source 805 into the reaction chamber 801, thereby exposing the surface of the substrate 813 to the reducing agent and, after a set period of time, the controller 819 closes the valve 806 to cease the flow of the reducing agent into the reaction chamber 801. As part of the second operation, during the flow of the reducing agent into the reaction chamber 801, the controller 819 may optionally be programed to pulse (turn on/off) the plasma discharge 818. The controller 819 may be programed to perform the first operation and the second operation, or vice versa. In some embodiments, the controller 819 is programed to perform the first operation and the second operation, wherein at least a portion of the first operation overlaps with at least a portion of the second operation such that the flow of the vanadium precursor into the reaction chamber 801 at least partially overlaps with the flow of the reducing agent into the reaction chamber 801. In certain other embodiments, the controller 819 is programed to sequentially perform the first operation followed by the second operation, or vice versa, such that the flow of the vanadium precursor into the reaction chamber 801 and the flow of the reducing agent into the reaction chamber 801 do not overlap. The controller may be further programed to repeat the first operation and the second operation one or more (n₁) times to form a (first) vanadium containing layer on the surface of the substrate 813.

In certain embodiments, the controller 819 is further configured and programed to perform at least one deposition cycle of a second cyclic deposition process to form a second vanadium containing layer (for example, the process according to FIG. 6 or FIG. 7). The controller 819 may be configured and programed to perform a third operation. In the third operation, the controller 819 opens the co-reactant source valve 808 to flow the co-reactant from the co-reactant source 807 into the reaction chamber 801, thereby exposing the surface of the substrate 813 to the co-reactant, after a set period of time, the controller 819 closes the co-reactant source valve 808 to cease the flow of the co-reactant into the reaction chamber 801. As part of the third operation, during the flowing of the co-reactant into the reaction chamber 801, the controller 819 may optionally be programmed to pulse (e.g., turn on/off) the plasma generator 819. In certain embodiments, the controller 819 is programed to perform the first operation and the third operation, or vice versa. In some of these embodiments, the controller 619 is programed to perform the first operation and the third operation, wherein at least a portion of the first operation overlaps with at least a portion of the third operation such that the flow of the vanadium precursor into the reaction chamber 801 at least partially overlaps with the flow of the co-reactant into the chamber 801. In other of these embodiments, the controller 819 is programed to sequentially perform the first operation followed by the third operation, or vice versa, such that the flow of the vanadium precursor into the reaction chamber 801 and the flow of the co-reactant into the reaction chamber 801 do not overlap. The controller may be further programed to repeat the first operation and the third operation one or more (n₂) times to form a second vanadium containing layer on the surface of the substrate 813.

In certain other embodiments, the controller 819 is further configured and programed to perform a third operation of continuously introducing the co-reactant into the reaction chamber. In these embodiments, in the third operation, the controller 819 opens the co-reactant source valve 808 to flow the co-reactant from the co-reactant source 807 into the reaction chamber 801, thereby exposing the surface of the substrate 813 to the co-reactant. As part of the third operation, during the flowing of the co-reactant into the reaction chamber 801, the controller 819 may optionally be programmed to turn on the plasma generator 819. After a set period of time, the controller 819 closes the co-reactant source valve 808 to cease the flow of the co-reactant into the reaction chamber 801 and may also turn off the plasma generator 819 if applicable.

As will be appreciated by one of skill in art, the controller 819 may be configured and programed to perform other operations. For example, the controller 819 may be operably connected to a purge gas source and configured and programed to open a valve to the purge gas source to flow the purge gas into the reaction space 801 and, after a set period of time, close the valve to the purge gas. In another example, the controller 819 may be operably connected to one or more thermocouples (not shown) and one or more heating elements (not shown) and configured and programed to measure and control a temperature of the at least one heating element to maintain a temperature of the substrate 813 at one or more set temperatures.

Further, it will be appreciated by one of skill in art that other configurations of the deposition assembly 800 are possible. For example, many arrangements of valves, conduits, precursor sources, reactant sources, carrier gas sources, and purge gas sources may be used to accomplish the goal of selectively feeding gases into the reaction chamber. Additionally, many chamber configurations are possible to achieve the goal of housing a substrate and flowing the various precursors, reactants, and other gasses across the surface of the substrate. Further multiple reaction chambers are possible. In this context, the reaction chamber 801 shown in FIG. 8 may represent one of many reaction chambers of a cluster tool, and the injector system 802 and/or the controller 819 may be connected to more than one reaction chambers. As a schematic representation of deposition assembly, many components have been omitted for simplicity of illustration, and such components may include, for example, various valves, manifolds, purifiers, flow controllers, heaters, containers, vents, and/or bypasses.

In some embodiments, a system for forming a first vanadium containing layer on a surface of a substrate comprises: a reaction space for accommodating a substrate; a vanadium precursor source for providing a vanadium precursor in gas communication via a vanadium precursor source valve with the reaction space; a reducing agent source for providing a reducing agent in gas communication via a reducing agent source valve with the reaction space; and a controller operably connected to the vanadium precursor source valve and the reducing agent source valve and configured and programmed to perform the methods disclosed herein for forming a first vanadium containing layer on a surface of the substrate, such as, for example, using the method provided in FIG. 5. The controller may be configured and programmed to perform at least one deposition cycle of a first cyclic deposition process comprising sequentially controlling: opening one of the vanadium precursor source valve and the reducing agent source valve; closing the one of the vanadium precursor source valve and the reducing agent source valve; opening the other of the vanadium precursor source valve and the reducing agent source valve; and closing the other of the vanadium precursor source valve and the reducing agent source valve. For example, the controller may be configured and programmed to perform at least one deposition cycle of a first cyclic deposition process comprising sequentially controlling: opening the vanadium precursor source valve to supply the vanadium precursor into the reaction space; closing the vanadium precursor source valve to cease the supply the vanadium precursor into the reaction space; opening the reducing agent source valve to supply the reducing agent into the reaction space; and closing the reducing agent source valve to cease the supply of the reducing agent into the reaction space. Additionally, or alternatively, the controller may be configured and programmed to perform at least one deposition cycle of a first cyclic deposition process comprising sequentially controlling: opening the reducing agent source valve to supply the reducing agent into the reaction space; closing the reducing agent source valve to cease the supply of the reducing agent into the reaction space; opening the vanadium precursor source valve to supply the vanadium precursor into the reaction space; and closing the vanadium precursor source valve to cease the supply the vanadium precursor into the reaction space. The controller may be further programed to sequentially repeat the opening of the vanadium precursor source valve and the closing of the vanadium precursor source valve, and the opening of the reducing agent source valve and the closing of the reducing agent source valve, or vice versa, one or more (n₁) times, to form a first vanadium containing layer on the surface of the substrate.

In some embodiments, the system for forming a vanadium containing layer on a surface of a substrate further comprises a co-reactant source for providing a co-reactant in gas communication via a co-reactant source valve with the reaction space and optionally a plasma unit comprising a plasma generator. The controller is operably connected to the co-reactant source valve and the plasma generator and configured and programmed to further perform the methods disclosed herein for forming a second vanadium containing layer. For example, in certain embodiments, the second vanadium containing layer comprises vanadium nitride and the controller may be configured and programmed to further perform the method shown in FIG. 6, where the co-reactant is a nitrogen reactant. In another example, in certain embodiments, the second vanadium containing layer comprise a vanadium chalcogenide and the controller may be configured and programmed to further perform the method shown in FIG. 7, where the co-reactant is a chalcogen reactant. In these embodiments, the controller may be further configured and programmed to control opening the co-reactant source valve to supply the co-reactant into the reaction space; and closing the co-reactant source valve to cease the supply the co-reactant into the reaction space. In some of these embodiments, the controller may be further configured and programmed to perform at least one deposition cycle of a second cyclic deposition process comprising sequentially controlling: opening one of the vanadium precursor source valve and the co-reactant source valve; closing the one of the vanadium precursor source valve and the co-reactant source valve; opening the other of the vanadium precursor source valve and the co-reactant source valve; and closing the other of the vanadium precursor source valve and the co-reactant source valve. The controller may optionally be programed to pulse the plasma generator For example, the controller may be configured and programmed to perform at least one deposition cycle of a second cyclic deposition process comprising sequentially controlling: opening the vanadium precursor source valve to supply the vanadium precursor into the reaction space; closing the vanadium precursor source valve to cease the supply the vanadium precursor into the reaction space; opening the co-reactant source valve to supply the co-reactant into the reaction space and optionally pulsing the plasma generator; and closing the co-reactant source valve to cease the supply of the co-reactant into the reaction space. Additionally, or alternatively, the controller may be configured and programmed to perform at least one deposition cycle of a second cyclic deposition process comprising sequentially controlling: opening the co-reactant source valve to supply the co-reactant into the reaction space and optionally pulsing the plasma generator; closing the co-reactant source valve to cease the supply of the co-reactant into the reaction space; opening the vanadium precursor source valve to supply the vanadium precursor into the reaction space; and closing the vanadium precursor source valve to cease the supply the vanadium precursor into the reaction space. The controller may be further programed to sequentially repeat the opening of the vanadium precursor source valve and the closing of the vanadium precursor source valve, and the opening of the co-reactant source valve and the closing of the co-reactant source valve, or vice versa, and optionally pulsing of the plasma generator, one or more (n₂) times, to form a second vanadium containing layer on the surface of the substrate.

In some embodiments, the system for forming one or more vanadium containing layers on a surface of a substrate further comprises a plasma unit comprising a plasma generator. In these embodiments, the controller is operably connected to the plasma unit and configured and programmed to further perform turning on the plasma generator and turning off the plasma generator during one or more of the supplying the vanadium precursor into the reaction space, the supplying the reducing agent into the reaction space, and the supplying the co-reactant into the reaction space.

Another aspect of the present disclosure is related to a reaction injector system comprising components for forming one or more vanadium containing layers (e.g., see 802 in FIG. 8). In some embodiments, the reaction injector system comprises at least one vanadium precursor vessel comprising the vanadium precursor and at least one a reducing agent vessels comprising the reducing agent, wherein the reaction injector system is configured to flow a vapor of the vanadium precursor from the at least one vanadium precursor vessel and to flow a vapor of the reducing agent from the at least one reducing agent vessel into a reaction space of a deposition assembly comprising a substrate. In some of these embodiments, the reaction injector system further comprises at least one a co-reactant vessel comprising a co-reactant, wherein the reaction injector system is configured to flow a vapor of the co-reactant from the at least one co-reactant vessel into the reaction space of the deposition assembly. The vanadium precursor, the reducing agent, and the co-reactant are described above.

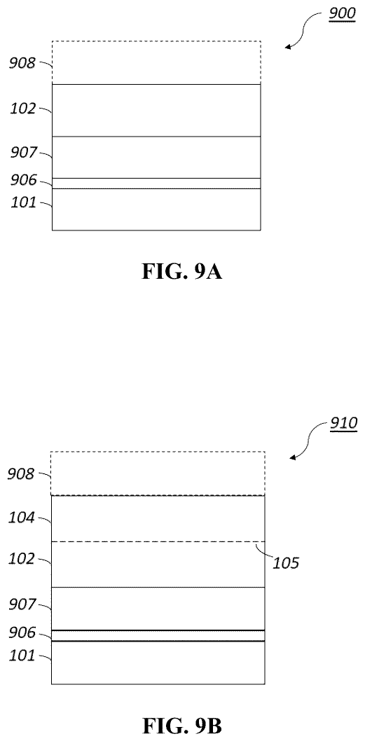

The vanadium containing layers disclosed herein may be useful in a variety of applications for semiconductor device manufacturing. For example, FIG. 9A and FIG. 9B show exemplary embodiments of a structure comprising one or more vanadium containing layers that are formed using the methods and systems disclosed herein. The structure can be or form part of a metal oxide semiconductor field effect transistors (MOSFET) and, in some instances, form part of a complementary metal-oxide-semiconductor (CMOS) device. In some embodiments, the semiconductor device structure may be an intermediate structure, for example, an intermediate MOSFET structure. In this context, “intermediate” refers to a structure that is partially formed and further processing steps are required to form the final structure. It should be understood that the structures shown in FIG. 9A and FIG. 9B can include other elements or other layers that are not explicitly shown and that the thicknesses of the various layers relative to one another are not drawn to scale.

FIG. 9A shows a pictorial representation of an exemplary structure 900 that comprises a (first) vanadium containing layer 102. The (first) vanadium containing layer 102 is formed using the methods disclosed herein (e.g., see FIG. 2). In some embodiments, the first vanadium containing layer comprises metallic vanadium. The structure 900 further comprises a substrate 101 and one or more dielectric layers, for example a first dielectric layer 906 and a second dielectric layer 907. The first dielectric layer 906 may be an oxide material, such as silicon dioxide. The second dielectric layer 907 may be a high-κ material layer. Non-limiting examples of high-κ materials include hafnium oxide (HfO₂), tantalum oxide (Ta₂O₅), zirconium oxide (ZrO₂), titanium oxide (TiO₂), hafnium silicate (HfSiOₓ), aluminum oxide (Al₂O₃), lanthanum oxide (La₂O₃), and combinations and mixtures thereof. The structure may further comprise an optional conducting layer 908. The structure 900 may comprise additional layers that are not explicitly shown in FIG. 9A. For example, in certain embodiments, the structure 900 may comprise TiN and/or MoN layers and/or other work function tuning layers, positioned cither under the first vanadium containing layer 102 above the dielectric layer 907 and/or above the first vanadium containing layer 102 below the optional conducting layer 908.

FIG. 9B shows a pictorial representation of another exemplary structure 910 that comprises a first vanadium containing layer 102 and a second vanadium contain layer 104. The first vanadium containing layer 102 and the second vanadium containing 104 are formed using the methods disclosed herein (e.g., see FIG. 3). In some embodiments, the second vanadium containing layer comprises vanadium nitride. In some other embodiments, the second vanadium containing layer comprises a vanadium chalcogenide, for example a vanadium dichalcogenide. As discussed above, the interface 105 between the first vanadium containing layer 102 and the second vanadium containing layer 104 is shown by a dashed line to indicate that the interface may be distinct or, alternatively, the interface may be less well defined or not defined at all. The structure 910 further comprises a substrate 101 and one or more dielectric layers, for example a first dielectric layer 906 and a second dielectric layer 907. The first and second dielectric layers (906 and 907) are discussed above. The structure 910 may further comprise an optional conducting layer 908. The structure 910 may comprise additional layers that are not explicitly shown in FIG. 9B. For example, in certain embodiments, the structure 910 may comprise TiN and/or MoN layers and/or other work function tuning layers, positioned either under the first vanadium containing layer 102 above the dielectric layer 907 and/or above the second vanadium containing layer 104 below the optional conducting layer 908.

Although certain embodiments and examples are disclosed herein, it will be understood by those skilled in the art that the disclosed compositions, methods, systems, and structures extend beyond the specifically disclosed embodiments and include all novel and nonobvious combinations and sub-combinations of the various compositions, methods, systems, and structures, as well as any and all equivalents thereof. It is to be understood that the compositions, methods, systems, and structures described herein are exemplary in nature, and that these specific embodiments or examples are not to be considered in a limiting sense, because numerous variations are possible. The specific methods and systems described herein may represent one or more of any number of processing strategies. Thus, the various acts illustrated may be performed in the sequence illustrated, in other sequences, or omitted in some cases. Moreover, various features of the disclosure are grouped together in one or more, aspects, embodiments, and configurations for the purpose of streamlining the disclosure. The features of the aspects, embodiments, and configurations of the disclosure may be combined in alternate aspects, embodiments, and configurations other than those discussed above. The compositions, methods, systems, and structures of the disclosure are not to be interpreted as reflecting an intention that the claimed disclosure requires more features than are expressly recited in each claim. Rather, as the following claims reflect, inventive aspects lie in less than all features of a single foregoing disclosed aspects, embodiments, and configurations. Thus, the following claims are hereby incorporated into this Detailed Description, with each claim standing on its own as a separate embodiment of the disclosure, and the features recited in the various dependent claims may be combined with one another in various combinations, as appropriate, to form other embodiment of the disclosure.

1. A method for forming a structure comprising one or more vanadium containing layers, the method comprising:
providing a substrate in a reaction space; and
forming a vanadium containing layer on a surface of the substrate by performing at least one deposition cycle of a cyclic deposition process comprising:
contacting a surface of the substrate with a vanadium precursor; and
contacting the surface of the substrate with a reducing agent, wherein the reducing agent comprises an organoindium compound.

2. The method of claim 1, wherein the vanadium precursor is a vanadium halide.

3. The method of claim 1, wherein the organoindium compound is an alkylindium compound.

4. The method of claim 1, wherein the vanadium precursor is selected from the group consisting of vanadium fluoride, vanadium chloride, vanadium bromide, vanadium iodide, vanadium oxyfluoride, vanadium oxychloride, vanadium oxybromide, vanadium oxyiodide, and combinations thereof, and the organoindium compound is selected from the group consisting of trimethylindium, triethylindium, tri-isopropylindium, tri-tertbutylindium, and combinations thereof.

5. The method of claim 1, wherein the vanadium containing layer comprises metallic vanadium.

6. The method of claim 1, wherein the at least one deposition cycle of the cyclic deposition process further comprises purging the reaction space between the contacting the surface of the substrate with the vanadium precursor and the contacting the surface of the substrate with the reducing agent.

7. The method of claim 1, wherein the method further comprises annealing the substrate at a temperature of at least about 400° C.

8. The method of claim 1, wherein the vanadium containing layer is a first vanadium containing layer, and the method further comprises, after the forming of the first vanadium containing layer, forming a second vanadium containing layer on the surface of the substrate.

9. The method of claim 8, wherein the forming of the second vanadium containing layer comprises contacting the surface of the substrate with a co-reactant comprising one or more of a nitrogen reactant and a chalcogen reactant.

10. The method of claim 9, wherein the cyclic deposition process to form the first vanadium containing layer is a first cyclic deposition process and the vanadium precursor is a first vanadium precursor, wherein the forming of the second vanadium containing layer comprises performing at least one deposition cycle of a second cyclic deposition process comprising:
contacting a surface of the substrate with a second vanadium precursor; and
contacting the surface of the substrate with the co-reactant.

11. The method of claim 8, wherein at least a portion of the first vanadium containing layer is converted to the second vanadium containing layer.

12. The method of claim 8, wherein the second vanadium containing layer is formed on or over the first vanadium containing layer.

13. The method of claim 8, wherein at least one of the vanadium containing layers comprises vanadium nitride.

14. The method of claim 8, wherein at least one of the vanadium containing layers comprises a vanadium chalcogenide.

15. The method of claim 8, wherein at least one of the vanadium containing layers comprises an electrical resistivity of less than 200 μΩ-cm at an average thickness of less than about 5 nm.

16. A structure comprising:
a substrate; and
one or more vanadium containing layers positioned on a surface of the substrate, wherein the structure is formed according to the method of claim 1.

17. The structure of claim 16, wherein structure comprises a first vanadium containing layer and a second vanadium containing layer, wherein the first vanadium containing layer comprises metallic vanadium and the second vanadium containing layer comprises vanadium nitride or a vanadium chalcogenide.

18. The structure of claim 16, further comprising one or more dielectric layers positioned on the surface of the substrate below the one or more vanadium containing layers, wherein at least one of the one or more dielectric layers comprises a high-κ material.

19. A vapor deposition assembly for depositing one or more vanadium containing layers comprising:
a reaction space for accommodating a substrate;
a vanadium precursor source for providing a vanadium precursor in gas communication via a vanadium precursor source valve with the reaction space;
a reducing agent source for providing a reducing agent in gas communication via a reducing agent source valve with the reaction space, wherein the reducing agent comprises an organoindium compound; and
a controller operably connected to the vanadium precursor source valve and the reducing agent source valve,
wherein the controller is configured and programmed to sequentially control:
opening the vanadium precursor source valve to supply the vanadium precursor into the reaction space;
closing the vanadium precursor source valve to cease the supply the vanadium precursor into the reaction space;
opening the reducing agent source valve to supply the reducing agent into the reaction space; and
closing the reducing agent source valve to cease the supply of the reducing agent into the reaction space.

20. The vapor deposition assembly of claim 19, further comprising a co-reactant source for providing a co-reactant in gas communication via a co-reactant source valve with the reaction space, wherein the controller is configured and programmed to control opening the co-reactant source valve to supply the co-reactant into the reaction space; and closing the co-reactant source valve to cease the supply the co-reactant into the reaction space. wherein the co-reactant comprises one or more of a nitrogen reactant and a chalcogen reactant.
